(19) United States
(12) Patent Application Publication
(10) Pub. No.: US 2017/0082929 A1
(43) Pub. Date: Mar. 23, 2017

(54) ILLUMINATION APPARATUS FOR A PROJECTION EXPOSURE SYSTEM

(71) Applicant: Carl Zeiss SMT GmbH, Oberkochen (DE)

(72) Inventors: Michael Patra, Oberkochen (DE); Markus Deguenther, Aalen (DE)

(21) Appl. No.: 15/368,942

(22) Filed: Dec. 5, 2016

Related U.S. Application Data
(63) Continuation of application No. PCT/EP2015/067728, filed on Jul. 31, 2015.

(30) Foreign Application Priority Data
Jul. 31, 2014 (DE) 102014215088.4
Nov. 10, 2014 (DE) 102014222884.0

(51) Int. Cl. G03F 7/20

(52) U.S. Cl. CPC G03F 7/70133

(57) ABSTRACT

For controlling an intensity distribution of an illumination radiation impinging on an object field, an illumination apparatus for a projection exposure apparatus for microlithography includes a mechanism for spatially displacing an illumination beam relative to a first facet mirror of an illumination optical unit.

### CROSS-REFERENCE TO RELATED APPLICATIONS

The present application is a continuation of, and claims benefit under 35 USC 120 to, international application PCT/EP2015/067728, filed Jul. 31, 2015, which claims benefit under 35 USC 119 of German Application No. 10 2014 215 088.4, filed Jul. 31, 2014 and German Application No. 10 2014 222 884.0, filed Nov. 10, 2014. The contents of International application PCT/EP2015/067728 and German Application Nos. 10 2014 215 088.4 and 10 2014 222 884.0 are incorporated herein by reference.

### FIELD

The disclosure relates to an illumination apparatus for a projection exposure system for microlithography. The disclosure additionally relates to an illumination system including such an illumination apparatus, and a projection exposure system for microlithography including such an illumination system. The disclosure additionally relates to a method for microlithographically producing a micro- or nanostructured component, and such a component.

### BACKGROUND

In the case of a lithographic patterning of a wafer, the radiation dose with which the wafer is exposed plays an important role. Dose fluctuations are translated directly into thickness fluctuations of the structures printed on the wafer. The dose with which a specific region on the wafer is exposed is dependent, inter alia, on the power of the illumination radiation in the region of an object field in which a reticle having structures to be imaged on the wafer is arranged. The power in turn is dependent on the components and properties of the illumination system for illuminating the object field.

### SUMMARY

The disclosure addresses the issue of improving an illumination apparatus for a projection exposure system including a plurality of illumination optical units.

The disclosure provides an illumination apparatus including a device for influencing at least one of individual output beams guided to illumination optical units, wherein the device has a regulation bandwidth of at least 1 kHz.

The regulation bandwidth is in particular in the range of 1 kHz to 50 kHz. It can be at least 2 kHz, in particular at least 3 kHz, in particular at least 5 kHz, in particular at least 10 kHz. It is preferably in the range of 5 kHz to 20 kHz.

The regulation bandwidth is closely linked with the response time of the device. The response time of the device is in particular at most 2 ms, in particular at most 1 ms, in particular at most 0.5 ms, in particular at most 0.3 ms, in particular at most 0.2 ms, in particular at most 0.1 ms, in particular at most 0.05 ms, in particular at most 0.03 ms, in particular at most 0.02 ms, in particular at most 0.01 ms.

The device thus makes it possible to influence very rapidly the individual output beams guided to the illumination optical units. In this case, a separate device of this type can be assigned in particular to each individual illumination optical unit.

The device enables in particular a very rapid control, in particular a very rapid regulation, of the dose of the illumination radiation which is guided to a specific illumination optical unit. It enables in particular a regulation of this radiation dose within the time required by a point on the wafer to be guided through the scanning slot. The device thus serves in particular for dose control.

The device can preferably be part of a regulation circuit. The regulation circuit can additionally include an energy sensor for detecting the intensity of the illumination radiation. The energy sensor can be arranged in the beam path in the illumination optical unit, that is to say upstream of the object field, in the region of the object plane or behind the latter. It can in particular also be arranged in the region of the image field, in particular on a wafer holder.

The device forms in particular a device for controlling an intensity distribution (I* (x, y)) of the illumination radiation impinging on an object field of one of the illumination optical units.

In accordance with one aspect of the disclosure, the device is arranged in each case in the beam path of the illumination radiation between the output coupling optical unit and one of the object fields. This enables an individual dose adaptation in different scanners.

In accordance with one aspect of the disclosure, the device has a mechanism for influencing a vignetting and/or absorption of the illumination radiation in one of the individual output beams. The device has in particular a mechanism for targeted influencing of the illumination radiation in one of the individual output beams.

According to the disclosure, it has been recognized that it is possible to be able to attenuate the illumination radiation in the individual output beams in a controlled and rapid manner. It has furthermore been recognized that, for a dose regulation, an influencing of the total intensity of the illumination radiation which is guided by one of the individual output beams to one of the object fields in the range of a few percent, in particular in the range of up to 10%, in particular in the range of 0.01% to 10%, can be sufficient to ensure a dose stability at the wafer. The amplitude of the influenceability of the total intensity is in particular in the range of 1% to 10%, in particular in the range of 1% to 5%.

In accordance with one aspect of the disclosure, the device has a mechanism for influencing an average gas density and/or a gas flow in a predetermined interaction region. The device has in particular a mechanism for influencing the average gas density in a predetermined volume region through which the illumination radiation of one of the individual output beams or of a part thereof passes on the path from the output coupling optical unit to the corresponding object field.

Altering the gas density makes it possible to control what proportion of the illumination radiation is absorbed by gas molecules.

In accordance with one aspect of the disclosure, for influencing the average gas density, provision is made of an actuatable apparatus for controlling a gas flow and/or an actuatable apparatus for evaporating liquid droplets. The latter can be generated in particular via a droplet generator.

The device can have in particular an apparatus for the actuator-based variation of the gas density and/or of the gas pressure or of a gas flow in the interaction region. The apparatus can have in particular a temperature control unit for controlling the temperature of the gas in the interaction region.

A suitable gas, in particular a suitable reaction gas for absorbing illumination radiation, is in particular one or more of the following elements: hydrogen, helium, chlorine, nitrogen, argon, oxygen, fluorine, krypton, neon and xenon.

The device can have in particular a control unit for controlling the pressure of the gas in the interaction region. The unit can include in particular a pressure reducing unit and/or a throttling unit.

The apparatus can have in particular a switchable valve, in particular having the switching rate of at least 1 kHz. The switching rate can be in particular at most 100 kHz.

The average gas density in the interaction region can also be influenced by evaporation of liquid droplets. The latter can be generated via a droplet generator with high frequency, in particular at least 1 kHz. The frequency of the droplet generator is in particular at most 100 kHz. The droplets can be generated periodically, in particular in a non-actuated manner. The droplet generation can also be controlled in an actuatable manner.

A laser, in particular, is provided for evaporating the droplets in the interaction region.

The droplets are composed in particular of a substance that is gaseous under normal conditions, in particular at 273.15 K and 101.325 kPa. In particular, one or more of the following elements are suitable for the droplets: hydrogen, helium, chlorine, nitrogen, argon, oxygen, fluorine, krypton, neon and xenon.

In accordance with one aspect of the disclosure, the device has a mechanism for displacing one or a plurality of vignetting elements relative to the individual output beam. In this case, it is possible to displace the vignetting element itself or the vignetting elements themselves and/or the individual output beam.

In accordance with a further aspect of the disclosure, the vignetting elements are selected from the following group: one or a plurality of pinhole stops, a microelement matrix, in particular a micromirror matrix, and aspherical particles that are alignable in an external force field.

All of these alternatives enable a rapid, precisely controllable influencing, in particular attenuation, of the total power of the illumination radiation of one of the individual output beams that is guided to a specific object field.

Aspherical particles that are alignable in an external force field are in particular elongate, rod-shaped particles. They can have an aspect ratio, defined by the ratio of the length of the shortest side to the length of the longest side, of at most 1:2, in particular at most 1:3, in particular at most 1:5, in particular at most 1:10. The particles can in particular be magnetic or have a magnetic moment. They can be aligned in particular with the aid of an external magnetic field.

The particles have in particular dimensions in the micrometres range. They can have in particular a diameter in the range of 1 μm to 10 μm, in particular in the range of 1 μm to 5 μm. They can have in particular a length in the range of 5 μm to 100 μm, in particular in the range of 10 μm to 50 μm.

In accordance with a further aspect of the disclosure, the device includes a mechanism for altering a radiation power emitted by the individual output beam into a specific phase space volume.

The phase space volume is understood here to mean the product of the angular divergence and the cross-sectional area of the illumination radiation, in particular of the individual output beam.

By varying the radiation power emitted into a specific phase space volume, it is possible in a simple manner to influence the radiation power of the illumination radiation impinging on the object field.

In accordance with one aspect of the disclosure, the device includes a mechanism for spatially displacing an individual illumination beam relative to an aperture-delimiting element of an illumination optical unit of the projection exposure apparatus. The aperture-delimiting element can be in particular a first facet mirror, in particular a field facet mirror. It can also be a stop.

In accordance with a further aspect of the disclosure, the device includes a mechanism for changing an area on which illumination radiation can impinge in the region of the first facet mirror. The device includes in particular a mechanism for influencing the divergence of the individual output beam.

The illumination apparatus is advantageous in particular for a projection exposure system in which a plurality of scanners are supplied with illumination radiation by a single, common radiation source. The illumination apparatus is advantageous in particular for a projection exposure system in which a plurality of illumination optical units are supplied with illumination radiation by a single, common radiation source in the form of a free electron laser (FEL) or in the form of a synchrotron radiation source.

The illumination apparatus according to the disclosure makes it possible, in particular, to individually control, in particular regulate, the radiation power of individual scanners, in particular of each individual scanner of a projection exposure system. It makes it possible, in particular, to individually control, in particular regulate, the input-side radiation power of each individual scanner. Via the control or regulation of the radiation power made available on the input side, the radiation dose for the exposure of wafers in the individual scanners can be individually controlled or regulated.

For regulating the radiation dose, as already mentioned provision can be made of a regulating loop including an energy sensor for detecting the radiation power impinging on a wafer.

The illumination apparatus can serve in particular for controlling the illumination radiation, in particular the radiation power of the illumination radiation, which is coupled into the illumination optical unit.

Such a mechanism for spatially displacing an illumination beam makes it possible, in a simple manner, to influence in a targeted manner the illumination radiation impinging on the first facet mirror and thus the illumination radiation impinging on the object field.

The mechanism for spatially displacing the individual illumination beam makes it possible, in particular, to displace a given intensity distribution relative to the first facet mirror. It is thereby possible, in a simple manner, to influence the radiation power reflected by the first facet mirror.

A spatial displacement of an individual illumination beam relative to the first facet mirror makes it possible to control in a targeted manner, in particular, what portion of the illumination radiation of the individual illumination beam impinges on the first facet mirror and thus contributes to the illumination of the object field, and what portion of the illumination radiation of the individual illumination beam does not impinge on the facet mirror and thus does not contribute to the illumination of the object field. A displacement of the individual illumination beam relative to the first facet mirror makes it possible to control in a targeted manner, in particular, what proportion of a given intensity distribution of the illumination radiation in the individual illumination beam is imaged into the object field.

The displacement of the individual illumination beam relative to the first facet mirror makes it possible to control in particular the intensity distribution of the illumination radiation impinging on the object field. This involves in particular a two-dimensional intensity distribution, I(x, y), wherein the y-direction is understood hereinafter to run parallel to a scanning direction. The x-direction runs perpendicularly thereto.

The mechanism for spatially altering a radiation power emitted by the individual output beam into a specific phase space volume, in particular for displacing the individual illumination beam, can be arranged in the beam path upstream of an intermediate focus, in particular in the beam path between the radiation source, in particular between the output coupling optical unit, and an intermediate focus. It can be arranged in particular outside, in particular upstream of, the actual illumination optical unit. A simple retrofitting of existing illumination optical units is possible in this case.

As an alternative thereto, the illumination apparatus, in particular the mechanism for displacing the individual illumination beam, can also form part of the illumination optical unit.

The mechanism for displacing the individual illumination beam can in particular also be arranged in the beam path between the intermediate focus and the first facet mirror in particular within the actual illumination optical unit.

The mechanism for displacing the individual illumination beam can also be arranged in or in direct proximity to the intermediate focus.

In accordance with a further aspect of the disclosure, the mechanism for displacing the individual illumination beam relative to the scanner is embodied in such a way that the individual illumination beam is displaceable in a direction parallel to a gradient of an intensity distribution, the gradient running in the y-direction, that is to say parallel to the scanning direction.

This makes it possible, in a simple manner, to control the radiation intensity impinging on the object field, without influencing the homogeneity of the illumination of the object field in a direction perpendicular to the scanning direction.

Particularly in the case of an individual illumination beam having an intensity distribution that is inhomogeneous in a direction parallel to the displacement direction, in particular has a gradient, such a displacement makes it possible, in a simple manner, to influence in a targeted manner the illumination radiation impinging on the first facet mirror, in particular on the object field.

The mechanism for displacing the individual illumination beam can be a mechanism for a pure displacement, that is to say a displacement in which the shape of the intensity distribution per se, which is also designated as intensity profile, is not altered.

The mechanism for displacing the individual illumination beam can also be a mechanism which, in addition to the displacement, leads to a change in the shape of the individual illumination beam, that is to say to a change in the intensity profile.

In accordance with one aspect of the disclosure, the illumination apparatus additionally includes a mechanism for shaping a beam bundle including predefined individual illumination beams from at least one beam bundle including a known collective illumination beam. It is thereby possible to generate the individual illumination beam which, according to the disclosure, is intended to be displaced relative to the first facet mirror, in particular relative to the object field.

I(x, y)=I(x)·exp[a(y+Δ)], wherein a and Δ are constants. Advantageously, I(x) is a constant.

The individual illumination beam can have in particular an intensity profile having a strictly monotonic progression. It can have a linear progression in the scanning direction. It advantageously has an exponential profile in the scanning direction:

What can be achieved via an exponential intensity profile is that the ratio of the intensities on field facets that are adjacent in the scanning direction remains unchanged during the displacement of the individual illumination beam.

In accordance with a further aspect of the disclosure, the intensity distribution has no gradient in the x-direction, ∂/∂x (I(x, y))=0.

It is thereby possible to ensure the homogeneity, in particular the uniformity, of the illumination of the object field perpendicularly to the scanning direction.

In accordance with one alternative, the intensity distribution also has no gradient in the y-direction, ∂/∂y (I(x, y))=0.

The intensity distribution can correspond in particular to a so-called flat-top profile.

By displacing the individual illumination beam relative to the first facet mirror, it is possible to achieve in particular a change in the average intensity in the region of the first facet mirror, in particular a change in the average intensity, in the region of the object field.

In accordance with a further aspect of the disclosure, the mechanism for displacing the individual illumination beam includes at least one actuator-displaceable and/or—deformable beam guiding element. The beam guiding element can be a mirror, in particular. The mirror can have in particular a simply connected reflection surface. The reflection surface of the mirror for displacing the illumination beam is embodied in particular in a continuous fashion, that is to say in a manner free of through openings, obscurations or other non-reflective interruptions.

The mirror is pivotable, in particular. It is pivotable in particular about a pivoting axis running parallel to a reflection surface of the first facet mirror, which will be described in even greater detail below. It is pivotable in particular about a pivoting axis running parallel to the x-direction. This should be understood to mean, in particular, that a pivoting of the beam guiding element leads to a displacement of the intensity distribution in a direction parallel to the scanning direction in the object field. In this case, the displacement of the illumination beam relative to the first facet mirror has the effect that the proportion of the intensity distribution which is guided by the first facet mirror to the object field is altered.

In accordance with one aspect of the disclosure, the mirror is displaceable via one, two or more actuators. The actuators can be piezo-actuators, in particular. The latter enable very rapid, precise displacement of the mirror.

Provision can be made, in particular, for arranging at least two piezo-actuators for displacing the mirror at a distance from one another. The actuators have in particular a distance in the range of 1 mm to 30 mm, in particular in the range of 3 mm to 20 mm, in particular in the range of 5 mm to 12 mm. The actuators are arranged in particular on the rear side of the mirror. They can be arranged in an edge region of the mirror. They can also be arranged in a central region of the mirror. The mirror can project in particular laterally beyond the actuators.

The beam guiding element is pivotable in particular by an angle of up to 10 mrad, in particular up to 20 mrad, in particular up to 50 mrad, in particular up to 100 mrad, in particular up to 200 mrad, in particular up to 500 mrad.

The mirror can also be embodied in a deformable fashion. A piezo-actuator can likewise serve for deforming the mirror.

In accordance with a further aspect of the disclosure, the beam guiding element has a surface profile which leads to a specific influencing of the intensity distribution of the individual illumination beam.

The beam guiding element can have in particular a surface profile which has the effect that an illumination beam having a predefined spatial intensity distribution is shaped from an illumination beam having a known intensity distribution.

In accordance with a further aspect of the disclosure, the mechanism for displacing the individual illumination beam is embodied in such a way that a ratio of a maximum displaceability of the individual illumination beam in a direction perpendicular to the direction of an optical axis to the extent of the individual illumination beam in the direction is at least 0.01, in particular at least 0.02, in particular at least 0.03, in particular at least 0.05, in particular at least 0.1, in particular at least 0.2, in particular at least 0.3, in particular at least 0.5, in particular at least 0.7, in particular at least 1. The maximum expedient displaceability of the individual illumination beam is given in practice by the dimensions of the components which are disposed downstream of the mechanism for displacing the individual illumination beam. The maximum displaceability is less than three times the extent of the cross section of the individual illumination beam.

The specified ratio of the maximum displaceability of the individual illumination beam to the extent thereof in the displacement direction relates, in particular, to a given position in the beam path, in particular to the region in which a field facet mirror is arranged, and/or to the region of the object plane.

The specified displacement direction is in particular the scanning direction or a direction parallel to the scanning direction or a direction corresponding to the scanning direction.

It has been found that such a scope of displacement is realistically possible. It has additionally been found that this is possible without allowing the inhomogeneity of the illumination on the field facet mirror to become excessively great. The relative inhomogeneity of the illumination on the field facet mirror is in particular less than 5, in particular less than 4, in particular less than 3. In this case, the relative inhomogeneity specifies the ratio of the highest radiation power that is reflected by an individual facet of the facet mirror to the minimum radiation power that is reflected by a facet of the facet mirror.

The change in the radiation power impinging on the object field, which change can be caused by the displacement of the individual illumination beam, is dependent in particular on the ratio of the scope of displacement to the dimensions of the object field. The ratio of the travel of the intensity distribution projected into the object plane to the extension of the object field, in particular in the scanning direction, is in particular in the range of 0.01 to 0.5, in particular in the range of 0.05 to 0.3, in particular in the range of 0.1 to 0.2.

The device includes in particular a mechanism for changing the intensity profile of the individual illumination beam. In other words, it enables a redistribution of the intensity of the illumination radiation. This is achievable in a simple manner in particular by a deformation of a beam guiding element. In particular, the homogeneity of the intensity distribution is maintained in this case. The total radiation power is additionally maintained. It is merely distributed over a different area. If this area projects in the scanning direction beyond the region of the facet mirror which contributes to the illumination of the object field, the projecting proportion is lost for the illumination of the object field. In other words, a reduction of the total radiation power impinging on the object field occurs.

Particularly if the intensity distribution is altered in such a way that a portion of the illumination radiation is lost in the region of the facet mirror because it is no longer imaged into the object field by facets, that is to say if the facet mirror is swamped, a displacement of the beam guiding element can be performed without any change in the area on which illumination radiation actually impinges in the region of the facet mirror. In this case, the facet mirror is completely illuminated, indeed even swamped. In this case, the intensity distribution of the illumination radiation impinging on the object field can be controlled by virtue of the fact that mechanisms for displacing the spatial intensity distribution determines that spatial region in the region of the facet mirror over which the illumination radiation is distributed overall. It is thereby possible to control the intensity, in particular the average intensity in the region of the facet mirror and thus the intensity of the illumination radiation transferred into the object field.

The control of the intensity distribution in the object field leads to an alteration—directly associated therewith—of the radiation dose that impinges on an image field, in particular a region of the surface of a wafer that is arranged in the image field. The illumination apparatus according to the disclosure thus enables in a simple manner a dose adaptation, in particular an adaptation of the radiation dose for the exposure of a wafer.

In accordance with a further aspect of the disclosure, the illumination apparatus includes a plurality of illumination optical units for transferring illumination radiation from a radiation source to an object field to be illuminated. The illumination apparatus includes in particular at least two illumination optical units. It can include three, four, five, six, seven, eight, nine, ten or more illumination optical units. The maximum number of illumination optical units is governed by the ratio of the radiation power emitted by the radiation source to the radiation power provided for illuminating the object field.

The illumination optical units include in each case at least one first facet mirror.

The illumination optical unit can in particular also include a second facet mirror. The facet mirrors can be in particular a field facet mirror and a pupil facet mirror. However, it is also possible to arrange the first facet mirror at a distance from a field plane or a conjugate plane with respect thereto and/or the second facet mirror at a distance from a pupil plane or a conjugate plane with respect thereto.

A further problem addressed by the disclosure is to improve an illumination system for a projection exposure system.

This problem is solved by an illumination system including at least one illumination apparatus in accordance with the above description and a radiation source for generating illumination radiation.

The radiation source can be an EUV radiation source, in particular. It can be a free electron laser (FEL), in particular. It can be a plasma source for EUV radiation, in particular. It can also be a synchrotron radiation source.

In accordance with a further aspect of the disclosure, the illumination system includes a plurality of illumination optical units. It can include in particular at least two, in particular at least three, in particular at least four, in particular at least five, illumination optical units.

The illumination optical units can be supplied with illumination radiation by a single common radiation source.

Illumination radiation can impinge on the illumination optical units in particular in parallel operation.

The illumination optical units can in each case be a part of a separate scanner with a separate projection optical unit.

The illumination system according to the disclosure makes it possible, in particular, to operate a plurality of scanners with a single radiation source, wherein it is possible, in particular, to control, in particular regulate, the radiation dose that impinges on a region on a wafer to be exposed in the image field in each of the scanners independently of one another.

It is possible, in particular, to individually regulate the radiation power at the input of each individual scanner.

In accordance with a further aspect of the disclosure, the illumination system includes at least two of the above-described mechanisms for altering the radiation power emitted by an individual output beam into a specific phase space volume. The illumination system can include in particular three, four, five, six or more mechanisms of this type. It can include in particular up to ten, in particular up to twenty, mechanisms of this type.

A further problem addressed by the disclosure is that of improving a projection exposure system for microlithography.

This problem is solved by a projection exposure system including an illumination system in accordance with the above description and at least two projection optical units for imaging the object fields into image fields.

In accordance with one aspect of the disclosure, the projection exposure system includes a plurality of projection optical units. It includes in particular two, three, four, five or more projection optical units. The number of projection optical units can correspond in particular precisely to the number of illumination optical units. In accordance with one aspect of the disclosure, a separate projection optical unit is assigned to each illumination optical unit.

The projection exposure system includes in particular a plurality of scanners which can be operated in parallel, that is to say simultaneously. In this case, each of the scanners has a mechanism for individual dose adaptation. Alternatively, all down to exactly one of the scanners have a mechanism for individual dose adaptation.

The further advantages are evident from those already described for the illumination system.

A further problem addressed by the disclosure is that of improving a method for microlithographically producing at least one micro- or nanostructured component.

This problem is solved by a method including the following steps:
providing a projection exposure system in accordance with the above description,
imaging a reticle arranged in the object field onto a wafer arranged in the image field for the purpose of exposing the wafer with illumination radiation with a predetermined radiation dose,
wherein, for adapting the radiation dose used for exposing the wafer, the intensity distribution of the illumination radiation impinging on the object field is controlled via the illumination apparatus.

The advantages of the method are evident from those of the illumination system.

With the aid of the illumination apparatus it is possible, in particular, to control, in particular regulate, in a simple manner the radiation dose used for the exposure of the wafer. It is possible, in particular, to control, in particular regulate, the radiation dose in a plurality of separate scanners, which are supplied with illumination radiation by a common radiation source, individually and independently of one another.

In accordance with one aspect of the disclosure, the time required for spacing the intensity distribution is shorter than the time required at most by a point in the object field to be driven through the object field. The displacement is in particular rapid in comparison with the time in which a point on the wafer passes through the scanning slot. The time required for the displacement is in particular at most 10 ms, in particular at most 5 ms, in particular at most 2 ms, in particular at most 1 ms, in particular at most 0.5 ms, in particular at most 0.3 ms, in particular at most 0.2 ms, in particular at most 0.1 ms, in particular at most 0.05 ms, in particular at most 0.03 ms, in particular at most 0.02 ms, in particular at most 0.01 ms. This is made possible in particular by the high regulation bandwidth of the device.

In accordance with a further aspect of the disclosure, illumination radiation impinges simultaneously on a plurality of wafers. Provision is made, in particular, for exposing a plurality of wafers simultaneously in separate scanners.

In this case, the radiation dose that impinges on each of the wafers can be controlled or regulated individually and independently of the other scanners. For details, reference should be made to the above description.

A further problem addressed by the disclosure is that of improving a micro- or nanostructured component.

This problem, too, is solved by the provision of the illumination apparatus according to the disclosure. The advantages are evident from those described for the illumination apparatus.

### BRIEF DESCRIPTION OF THE DRAWINGS

Further details and particulars and also advantages of the disclosure are evident from the description of exemplary embodiments with reference to the drawings, in which:

FIG. 1 schematically shows a projection exposure apparatus for EUV projection lithography,

FIG. 2 schematically shows an excerpt from the beam path in a system including a plurality of projection exposure apparatuses in accordance with FIG. 1,

FIG. 3 shows an alternative schematic illustration of the beam path in a system including a plurality of projection exposure apparatuses,

FIG. 4 shows a schematic illustration of a device for controlling an intensity distribution with a mechanism for spatially displacing an illumination beam,

FIG. 5 schematically shows an intensity distribution of the illumination radiation in a projection exposure apparatus in the region of a field facet mirror,

FIG. 6 shows an illustration in accordance with FIG. 5 in a state in which the intensity profile was displaced relative to the field facet mirror,

FIG. 7 shows an illustration corresponding to that in FIG. 5 with an exponential intensity profile,

FIG. 8 schematically shows an illustration of a further device for displacing an illumination beam relative to the field facet mirror,

FIG. 9 shows an illustration in accordance with FIG. 4 of an alternative embodiment, in which the mirror for displacing the illumination beam has a specific surface profile for generating a specific intensity profile of the illumination beam,

FIG. 10 shows an illustration in accordance with FIG. 5 with a flat-top profile,

FIG. 11 shows an illustration in accordance with FIG. 10 but with a displaced and in the process altered flat-top profile,

FIG. 12 shows a schematic illustration of an alternative with a deformable mirror in a first deformation state, and

FIG. 13 shows an illustration in accordance with FIG. 12 with the mirror in a second deformation state,

FIG. 14 shows, in a sectional view parallel to the plane of incidence on the deflection mirrors, highly schematically an embodiment of the deflection optical unit with, in the beam path of the EUV individual output beam, firstly two convex cylindrical mirrors, a downstream plane mirror and three downstream concave cylindrical mirrors;

FIG. 15 shows, in an illustration similar to FIG. 14, a further embodiment of the deflection optical unit with a convex cylindrical mirror and three concave cylindrical mirrors that are sequentially adjacent in the EUV beam path;

FIG. 16 shows, in an illustration similar to FIG. 14, a further embodiment of the deflection optical unit with a convex cylindrical mirror, a plane mirror and two concave cylindrical mirrors arranged one after another sequentially in the EUV beam path;

FIG. 17 shows, in an illustration similar to FIG. 14, a further embodiment of the deflection optical unit with a convex cylindrical mirror, a plane mirror and three concave cylindrical mirrors arranged one after another sequentially in the EUV beam path;

FIG. 18 shows, in an illustration similar to FIG. 14, a further embodiment of the deflection optical unit with a convex cylindrical mirror, two downstream concave cylindrical mirrors, a downstream plane mirror and two downstream concave cylindrical mirrors arranged one after another sequentially in the EUV beam path;

FIG. 19 shows, in an illustration similar to FIG. 14, a further embodiment of the deflection optical unit with a convex cylindrical mirror, a downstream plane mirror and four sequentially downstream concave cylindrical mirrors arranged one after another sequentially in the EUV beam path;

FIG. 20 shows, in an illustration similar to FIG. 14, a further embodiment of the deflection optical unit with a convex cylindrical mirror, two sequentially downstream plane mirrors and three sequentially downstream concave cylindrical mirrors arranged one after another sequentially in the EUV beam path;

FIGS. 21 to 23 show schematic illustrations of an alternative device for influencing an individual output beam in different activation states;

FIGS. 24 and 25 show schematic illustrations of a further alternative form influencing an individual output beam in different positions;

FIG. 26 shows a schematic illustration of an alternative arrangement of a device for influencing only a portion of the illumination radiation in one of the individual output beams;

FIG. 27 shows a schematic illustration of a further alternative for influencing a portion of the illumination radiation in one of the individual output beams;

FIG. 28 shows a schematic illustration of a further alternative for influencing the illumination radiation in one of the individual output beams; and

FIG. 29 shows a further alternative of a device for influencing the illumination radiation in one of the individual output beams.

### DETAILED DESCRIPTION

A projection exposure apparatus 1 for microlithography is part of a projection exposure system 30 including a plurality of projection exposure apparatuses 1. The projection exposure apparatuses 1 in each case include an illumination optical unit 15 and a projection optical unit 19. The illumination optical unit 15 serves for transferring illumination radiation 3 from a radiation source 2 to a reticle 12 arranged in an object field 11. The projection optical unit 19 serves for imaging the reticle 12, in particular for imaging structures on the reticle 12, onto a wafer 24 arranged in an image field 22.

The individual parts of the projection exposure system 30 can be combined conceptually to form subsystems. These subsystems can form separate structural subsystems. However, the division into subsystems need not necessarily be reflected in a structural delimitation. By way of example, the illumination optical unit 15 and the projection optical unit 19 are in each case parts of an optical system. They are in particular parts of a scanner 5. The scanner 5 can also include further parts. It can include in particular the input coupling optical unit 14. It can also include the deflection optical unit 13. It can include in particular the entire beam guiding optical unit 10. The scanner 5 can include in particular in each case the parts which are arranged in the beam path downstream of the output coupling optical unit, that is to say in the beam path of one of the beams coupled out.

The radiation source 2, just like a beam shaping optical unit 6 disposed downstream thereof in the beam path of the illumination radiation 3 and just like an output coupling optical unit 8, is part of a radiation source module.

A beam guiding optical unit 10 includes, in the order of the beam path of the illumination radiation 3 in each case a deflection optical unit 13, an input coupling optical unit, in particular in the form of a focusing assembly 14, and the illumination optical unit 15.

The beam guiding optical unit 10 together with the beam shaping optical unit 6 and the output coupling optical unit 8 form parts of an illumination apparatus 35.

The illumination apparatus 35, just like the radiation source 2, is part of an illumination system.

The projection exposure system 30 includes the illumination system and a plurality of projection optical units 19. In this case, the number of projection optical units 19 corresponds in particular precisely to the number of illumination optical units 15, in particular of beam guiding optical units 10. There is in particular a 1:1 assignment between the illumination optical units 15 and the projection optical units 19.

In some instances the entire projection exposure system 30 is also designated as projection exposure apparatus. Hereinafter, for the sake of better conceptual delimitation, the projection exposure apparatuses 1 should be understood to be in each case that part of the projection exposure system 30 which serves for the exposure of an individual wafer 24, that is to say includes in each case exactly an individual one of the projection optical units 19. For this purpose, a plurality, in particular all, of the projection exposure apparatuses 1 share a common radiation source module, in particular a common radiation source 2.

The system including the projection exposure apparatuses 1 includes in particular a plurality of scanners 5 which are supplied with illumination radiation 3 by a single, common radiation source 2.

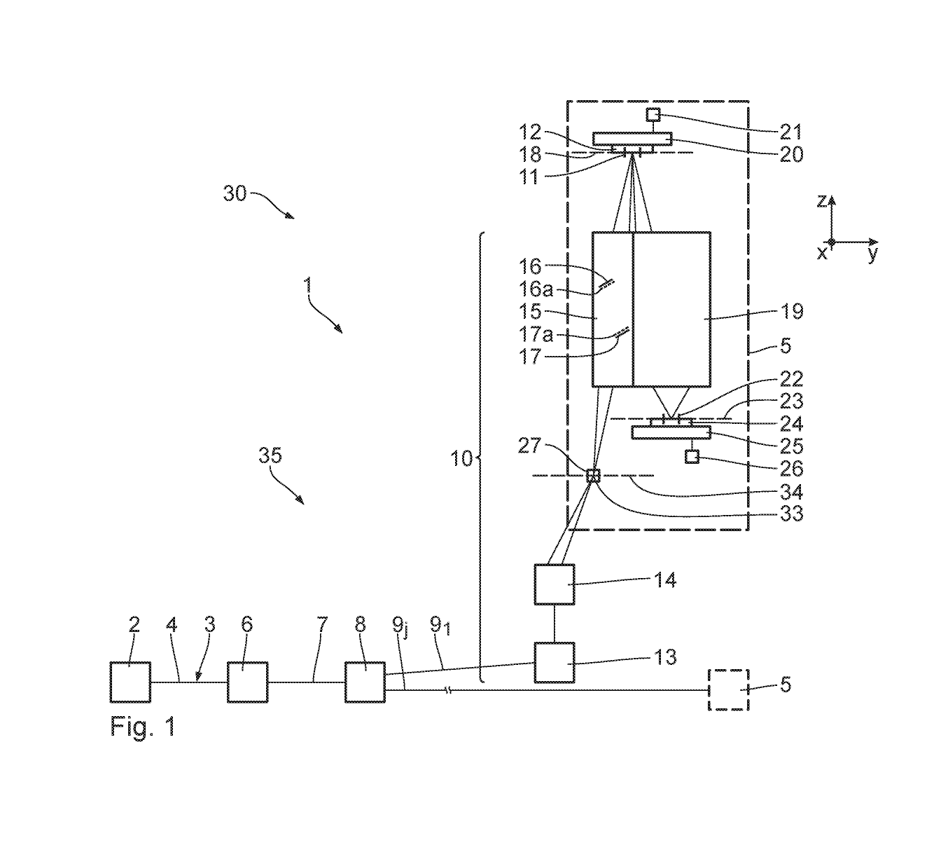

Only one of the projection exposure apparatuses 1 is illustrated schematically in FIG. 1. The projection exposure apparatus 1 serves for producing a micro- or nanostructured component, in particular an electronic semiconductor component. The projection exposure apparatuses 1 have a common radiation source 2. The radiation source 2 emits EUV radiation in the wavelength range of, for example, between 2 nm and 30 nm, in particular between 2 nm and 15 nm. The radiation source 2 is embodied as a free electron laser (FEL). It is a synchrotron radiation source or a synchrotron radiation-based radiation source which generates coherent radiation having very high brilliance. By way of example, for such radiation sources reference should be made to US 2007/0152171 A1, DE 103 58 225 B3 and the publications indicated in WO 2009/121438 A1.

The radiation source 2 has for example an average power in the range of 1 kW to 25 kW. It has a pulse frequency in the range of 10 MHz to 50 MHz. Each individual radiation pulse can amount to an energy of 83 μJ, for example. In the case of a radiation pulse length of 100 fs, this corresponds to a radiation pulse power of 833 MW.

The radiation source 2 can have a repetition rate in the kilohertz range, for example of 100 kHz, or in the low megahertz range, for example 3 MHz, in the medium megahertz range, for example 30 MHz, in the upper megahertz range, for example 300 MHz, or else in the gigahertz range, for example 1.3 GHz.

A cartesian xyz-coordinate system is used hereinafter for facilitating the representation of positional relationships. In these illustrations, the x-coordinate together with the y-coordinate regularly spans a beam cross section of the EUV radiation 3. Correspondingly, the z-direction regularly runs in the beam direction of the EUV radiation 3, which is also designated as illumination or imaging radiation.

In the region of an object plane 18 and respectively an image plane 23, the y-direction runs parallel to a scanning direction. The x-direction runs perpendicularly to the scanning direction.

The main components of one of the projection exposure apparatuses 1 are illustrated highly schematically in FIG. 1.

The radiation source 2 emits illumination radiation 3 in the form of an EUV raw beam 4. The EUV raw beam 4 has an intensity profile having a known intensity distribution I₀(x, y). The EUV raw beam 4 has a very low divergence.

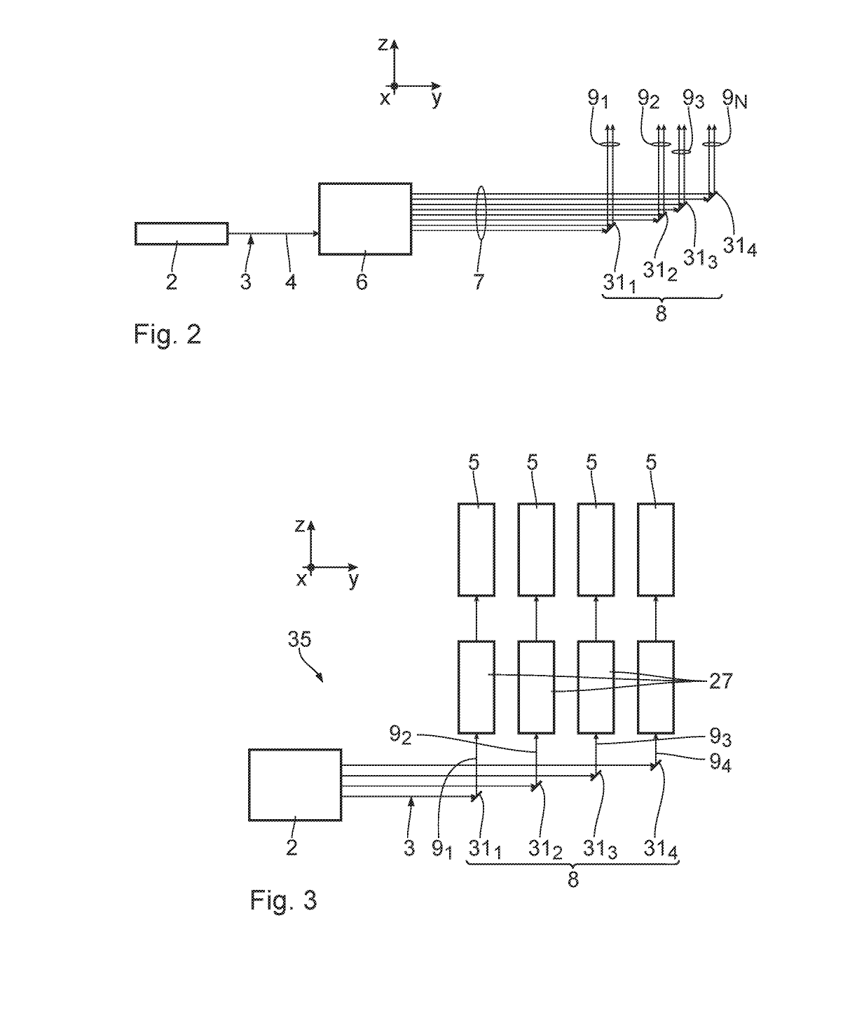

A beam shaping optical unit 6 serves for generating an EUV collective output beam 7 from the EUV raw beam 4. This is illustrated very highly schematically in FIG. 1 and somewhat less highly schematically in FIG. 2. The EUV collective output beam 7 has a very low divergence.

After leaving the beam shaping optical unit 6, the rays of the EUV collective output beam 7 run substantially parallel. The divergence of the EUV collective output beam 7 can be less than 10 mrad, in particular less than 1 mrad, in particular less than 100 gad, in particular less than 10 gad.

The EUV collective output beam 7 has an aspect ratio that is predefined by the beam shaping optical unit 6 in a manner dependent on a number N of scanners to be supplied by the radiation source 2. As will be explained in even greater detail below, provision is made for supplying a plurality of scanners with EUV radiation 3 via a single, common radiation source 2.

A system design where N=4 is indicated schematically in FIG. 2. In the case of the alternative illustrated schematically in FIG. 2, the radiation source 2 supplies four projection exposure apparatuses with EUV radiation 3. The number N of projection exposure apparatuses supplied or to be supplied with illumination radiation 3 by the radiation source 2 can also be even greater. It can be for example up to ten, in particular up to twenty.

An output coupling optical unit 8 serves for generating a plurality, namely N, of EUV individual output beams 9ᵢ(i=1 to N) from the EUV collective output beam 7. The EUV individual output beams 9ᵢ in each case form beams for illuminating a reticle 12. They are also designated as individual illumination beams or just as illumination beams.

FIG. 1 schematically illustrates the further guidance of one of the EUV individual output beams 9ᵢ, namely of the EUV individual output beam 9₁. The other EUV individual output beams 9ⱼ which are generated by the output coupling optical unit 8 and which are likewise indicated schematically in FIG. 1 are fed to other scanners 5 of the system.

FIG. 2 shows one example of the output coupling optical unit 8 for generating the EUV individual output beams 9ᵢ from the EUV collective output beam 7. The output coupling optical unit 8 has a plurality of output coupling mirrors 31ᵢ which are assigned to the EUV individual output beams 9ᵢ. The output coupling mirrors 31ᵢ in each case serve to couple out one of the EUV individual output beams 9ᵢ from the EUV collective output beam 7.

At the output of the output coupling optical unit 8, the EUV individual output beam 9ᵢ in each case has a known intensity distribution Iᵢ(x, y).

FIG. 2 shows an arrangement of the output coupling mirrors 31ᵢ in such a way that the illumination radiation 3 is deflected by 90° during the output coupling by the output coupling mirrors 31ᵢ. In accordance with one advantageous alternative, the output coupling mirrors 31ᵢ are in each case arranged in such a way that they are operated with grazing incidence of the illumination radiation 3. An angle of incidence of the illumination radiation 3 on the output coupling mirrors 31ᵢ can be at least 70°, in particular at least 80°, in particular at least 85°.

The output coupling mirrors 31ᵢ can in each case be thermally coupled to a heat sink (not illustrated in greater detail).

FIG. 2 illustrates one variant of the output coupling optical unit 8 including a total of four output coupling mirrors 31₁ to 31₄. A different number of output coupling mirrors 31ᵢ is also possible. Depending on the number of scanners 5 to be supplied by the radiation source 2, two, three, four, five, six, seven, eight, nine, ten or more output coupling mirrors 31ᵢ can be provided. The number of output coupling mirrors 31ᵢ is usually less than 20.

Downstream of the output coupling optical unit 8, the illumination radiation 3 is guided by the beam guiding optical unit 10 to the object field 11 of the scanner 5. A lithography mask in the form of the reticle 12 as object to be projected is arranged in the object field 11.

The deflection optical unit 13 situated downstream of the output coupling optical unit 8 in the beam path of the illumination radiation 3 serves firstly for deflecting the EUV individual output beams 9ᵢ such that the latter in each case have a vertical beam direction downstream of the deflection optical unit 13, and secondly for adapting the x:y-aspect ratio of the EUV individual output beams 9ᵢ. The x:y-aspect ratio of the EUV individual output beams 9ᵢ can be adapted in particular to an aspect ratio of 1:1 via the deflection optical unit 13. Other aspect ratios can likewise be achieved. It is possible, in particular, to adapt the EUV individual output beams 9ᵢ in each case in such a way that they have an x:y-aspect ratio of the first facets 16a and/or corresponding to that of the object field 11, in particular for example an aspect ratio of 13:1.

In one variant in which a vertical beam path of the EUV individual output beams 9ᵢ is already present downstream of the output coupling optical unit 8, a deflecting effect of the deflection optical unit 13 can be dispensed with. In this case, the deflection optical unit 13 serves primarily for adapting the x:y-aspect ratio of the EUV individual output beams 9ᵢ.

In accordance with one variant, the deflection optical unit 13 can be dispensed with altogether.

Downstream of the deflection optical unit 13, the EUV individual output beams 9 can pass in such a way that, if appropriate after passing through a focusing assembly 14, they are incident in the illumination optical unit 15 at an angle, wherein this angle allows efficient folding of the illumination optical unit. Downstream of the deflection optical unit 13, the EUV individual output beam 9ᵢ can pass at an angle of 0° to 10° with respect to the perpendicular, at an angle of 10° to 20° with respect to the perpendicular, or at an angle of 20° to 30° with respect to the perpendicular.

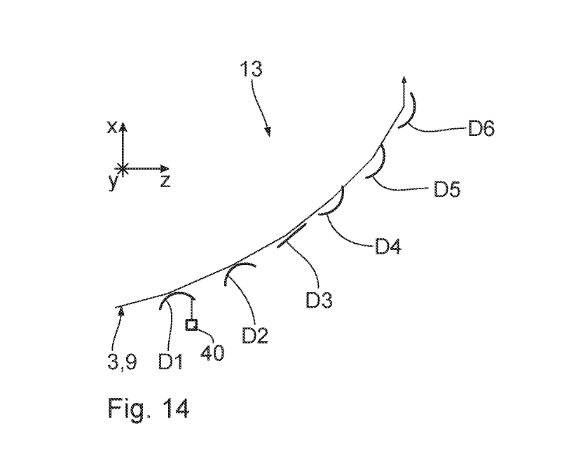

Different variants for the deflection optical unit 13 are described below with reference to FIGS. 14 to 20. In this case, the illumination light 3 is illustrated schematically as a single ray, that is to say that a beam representation is dispensed with.

The divergence of the EUV individual output beams 9ᵢ after passing through the deflection optical unit is less than 10 mrad, in particular less than 1 mrad and in particular less than 100 gad, that is to say that the angle between two arbitrary rays in the beam of rays of the EUV individual output beam 9ᵢ is less than 20 mrad, in particular less than 2 mrad and in particular less than 200 gad. It is fulfilled for the variants described below.

The deflection optical unit 13 according to FIG. 14 deflects the coupled-out EUV individual output beam 9 overall by a deflection angle of approximately 75°. The EUV individual output beam 9 is therefore incident on the deflection optical unit 13 according to FIG. 14 at an angle of approximately 15° with respect to the horizontal and leaves the deflection optical unit 13 with a beam direction parallel to the x-axis in FIG. 14. The deflection optical unit 13 has a total transmission for the EUV individual output beam 9 of approximately 55%.

The deflection optical unit 13 according to FIG. 14 has a total of six deflection mirrors D1, D2, D3, D4, D5 and D6, which are numbered consecutively in the order of their impingement in the beam path of the illumination light 3. Only a section through the reflection surface of the deflection mirrors D1 to D6 is illustrated schematically in each case, wherein a curvature of the respective reflection surface is illustrated in a greatly exaggerated fashion. All of the mirrors D1 to D6 of the deflection optical unit 13 according to FIG. 14 are impinged on by the illumination light 3 with grazing incidence in a column deflection plane of incidence parallel to the xz-plane.

The mirrors D1 and D2 are embodied as convex cylindrical mirrors with the cylinder axis parallel to the y-axis. The mirror D3 is embodied as a plane mirror. The mirrors D4 to D6 are embodied as concave cylindrical mirrors once again with the cylinder axis parallel to the y-axis.

The convex cylindrical mirrors are also designated as domed mirrors. The concave cylindrical mirrors are also designated as dished mirrors.

The combined beam shaping effect of the mirrors D1 to D6 is such that the x/y-aspect ratio is adapted from the value 1/\sqrt{N}:1 to the value 1:1. In the x-dimension, therefore, in the ratio the beam cross section is stretched by the factor 1\sqrt{N}.

At least one of the deflection mirrors D1 to D6, a selection of the deflection mirrors or else all of the deflection mirrors D1 to D6 can be embodied as displaceable in the x-direction and/or in the z-direction via assigned actuators 40. An adaptation firstly of the deflection effect and secondly of the aspect ratio adapting effect of the deflection optical unit 13 can be brought about as a result. Alternatively or additionally, at least one of the deflection mirrors D1 to D6 can be embodied as a mirror that is adaptable with regard to its radius of curvature. For this purpose, the respective mirror D1 to D6 can be constructed from a plurality of individual mirrors which are actuator-displaceable with respect to one another, this not being illustrated in the drawing.

The various optical assemblies of the system including the projection exposure apparatuses 1 can be embodied adaptively. It is thus possible to predefine centrally how many of the projection exposure apparatuses 1 are intended to be supplied with EUV individual output beams 9ᵢ by the light source 2 with what energetic ratio and what beam geometry is intended to be present in the case of the respective EUV individual output beam 9ᵢ after passing through the respective deflection optical unit 13. Depending on predefined values, the EUV individual output beams 9ᵢ can differ in terms of their intensity and also in terms of the desired x/y-aspect ratio. In particular, it is possible for the energetic ratios of the EUV individual output beams 9ᵢ to be varied by adaptive setting of the output coupling mirrors 31ᵢ, and for the size and the aspect ratio of the EUV individual output beams 9ᵢ to be kept unchanged after passing through the deflection optical unit 13 by adaptive setting of the deflection optical unit 13.

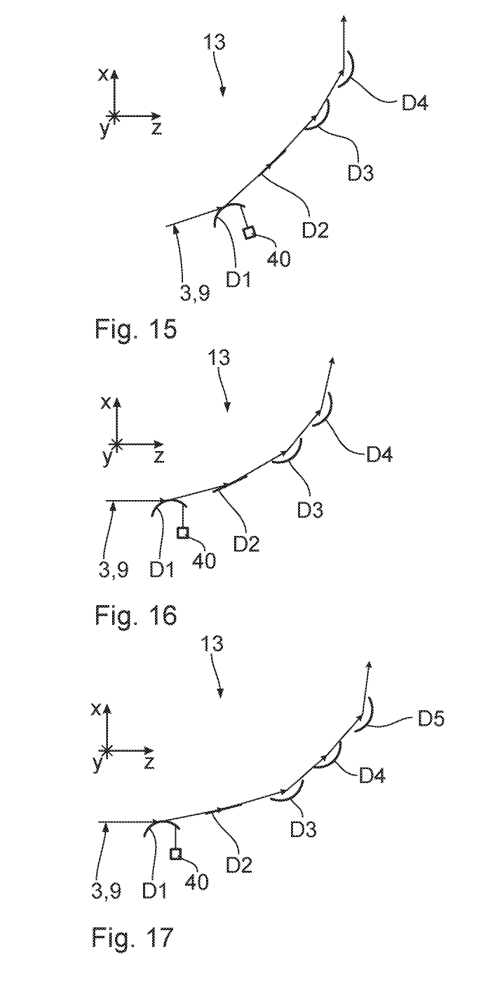

With reference to FIGS. 15 to 20, a description is given below of further embodiments of deflection optical units which can be used instead of the deflection optical unit 13 according to FIG. 14 in a system including N projection exposure apparatuses 1. Components and functions which have already been explained above with reference to FIGS. 1 to 14, and in particular with reference to FIG. 14, bear the same reference signs and will not be discussed in detail again.

A deflection optical unit 13 according to FIG. 15 has a total of four mirrors D1, D2, D3, D4, in the beam path of the illumination light 3. The mirror D1 is embodied as a convex cylindrical lens. The mirrors D2 to D4 are embodied as concave cylindrical lenses.

More precise optical data can be gathered from the following table. In this case, the first column denotes the radius of curvature of the respective mirror D1 to D4 and the second column denotes the distance from the respective mirror D1 to D3 to the respective downstream mirror D2 to D4. The distance relates to that distance which is covered by a central ray within the EUV individual output beam 9ᵢ between the corresponding reflections. The unit used in this table and the subsequent tables is mm in each case, unless described otherwise. The EUV individual output beam 9ᵢ is incident in the deflection optical unit 13 in this case with a semidiameter dᵢₙ/2 of 10 mm.

Table regarding FIG. 15

| | Radius of curvature | Distance to the next mirror |
|---|---|---|
| D1 | 2922.955800 | 136.689360 |
| D2 | −49802.074797 | 244.501473 |
| D3 | −13652.672229 | 342.941568 |
| D4 | −22802.433560 | |

The deflection optical unit 13 according to FIG. 15 expands the x/y-aspect ratio by a factor of 3.

FIG. 16 shows a further embodiment of a deflection optical unit 13 likewise including four mirrors D1 to D4. The mirror D1 is a convex cylindrical mirror. The mirror D2 is a plane mirror. The mirrors D3 and D4 are two cylindrical mirrors having an identical radius of curvature.

More precise data can be gathered from the following table, which corresponds to the table regarding FIG. 15 in terms of layout.

Table regarding FIG. 16

| | Radius of curvature | Distance to the next mirror |
|---|---|---|
| D1 | 5080.620899 | 130.543311 |
| D2 | 0.000000 | 187.140820 |
| D3 | −18949.299940 | 226.054877 |
| D4 | −18949.299940 | |

The deflection optical unit 13 according to FIG. 16 expands the x/y-aspect ratio of the EUV individual output beam 9 by a factor of 2.

FIG. 17 shows a further embodiment of a deflection optical unit 13 including five mirrors D1 to D5. The first mirror D1 is a convex cylindrical mirror. The second mirror D2 is a plane mirror. The further mirrors D3 to D5 are three concave cylindrical mirrors.

More precise data can be gathered from the following table, which corresponds to the tables regarding FIGS. 15 and 16 in terms of layout.

Table regarding FIG. 17

| | Radius of curvature | Distance to the next mirror |
|---|---|---|
| D1 | 3711.660251 | 172.323866 |
| D2 | 0.000000 | 352.407636 |
| D3 | −27795.782391 | 591.719804 |
| D4 | −41999.478002 | 717.778100 |
| D5 | −101011.739006 | |

The deflection optical unit 13 according to FIG. 17 expands the x/y-aspect ratio of the EUV individual output beam 9 by a factor of 5.

A further embodiment of the deflection optical unit 13 differs from the embodiment according to FIG. 17 only in the radii of curvature and the mirror distances, which are indicated in the following table:

Table “alternative design regarding FIG. 17”

| | Radius of curvature | Distance to the next mirror |
|---|---|---|
| D1 | 4283.491081 | 169.288384 |
| D2 | 0.000000 | 318.152124 |
| D3 | −26270.138665 | 486.408438 |
| D4 | −41425.305704 | 572.928893 |
| D5 | −91162.344644 | |

In contrast to the first embodiment according to FIG. 17, this alternative design has an expansion factor of 4 for the x/y-aspect ratio.

Yet another embodiment of the deflection optical unit 13 differs from the embodiment according to FIG. 17 in the radii of curvature and the mirror distances, which are indicated in the following table:

Table “further alternative design” regarding FIG. 17

| | Radius of curvature | Distance to the next mirror |
|---|---|---|
| D1 | 5645.378471 | 164.790501 |
| D2 | 0.000000 | 269.757678 |
| D3 | −28771.210382 | 361.997270 |
| D4 | −55107.732703 | 424.013033 |
| D5 | −55107.732703 | |

In contrast to the embodiment described above, this further alternative design has an expansion factor of 3 for the x/y-aspect ratio. The radii of curvature of the last two mirrors D4 and D5 are identical.

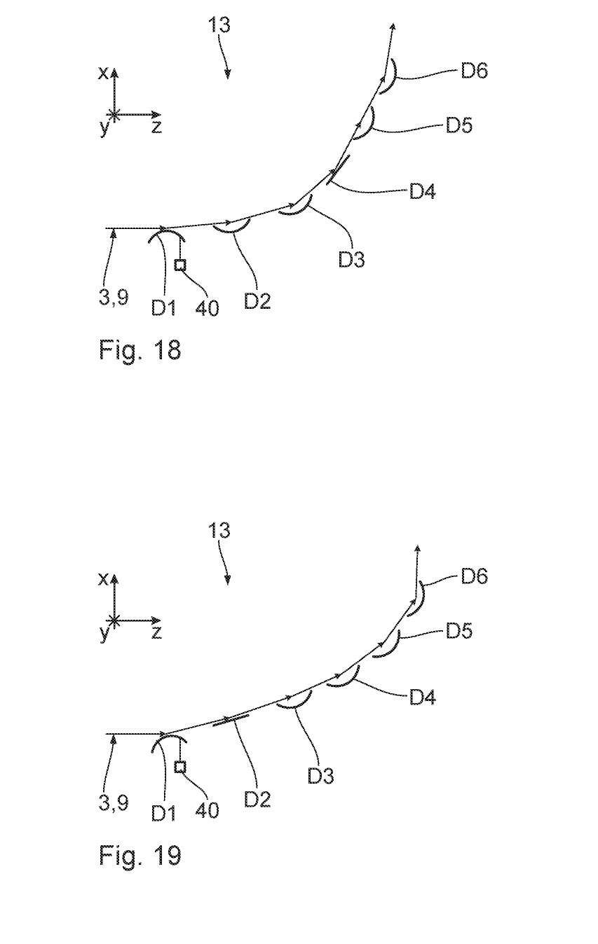

FIG. 18 shows a further embodiment of a deflection optical unit 13 including six mirrors D1 to D6. The first mirror D1 is a convex cylindrical mirror. The next two deflection mirrors D2, D3 are in each case concave cylindrical mirrors having an identical radius of curvature. The next deflection mirror D4 is a plane mirror. The last two deflection mirrors D5, D6 of the deflection optical unit 13 are once again concave cylindrical mirrors having an identical radius of curvature.

More precise data can be gathered from the following table, which corresponds to the table regarding FIG. 17 in terms of layout.

Table regarding FIG. 18

| | Radius of curvature | Distance to the next mirror |
|---|---|---|
| D1 | 7402.070457 | 197.715713 |
| D2 | −123031.042588 | 332.795789 |
| D3 | −123031.042588 | 459.491141 |
| D4 | 0.000000 | 608.342998 |
| D5 | −87249.129389 | 857.423893 |
| D6 | −87249.129389 | |

The deflection optical unit 13 in accordance with FIG. 18 has an expansion factor of 5 for the x/y-aspect ratio.

FIG. 19 shows a further embodiment of a deflection optical unit 13 including six mirrors D1 to D6. The first mirror D1 of the deflection optical unit 13 is a convex cylindrical mirror. The downstream second deflection mirror D2 is a plane mirror. The downstream deflection mirrors D3 to D6 are in each case concave cylindrical mirrors. The radii of curvature of the mirrors D3 to D4, on the one hand, and of the mirrors D5 and D6, on the other hand, are identical.

More precise data can be gathered from the following table, which corresponds to the table regarding FIG. 18 in terms of layout.

Table regarding FIG. 19

| | Radius of curvature | Distance to the next mirror |
|---|---|---|
| D1 | 7950.882348 | 196.142128 |
| D2 | 0.000000 | 322.719989 |
| D3 | −207459.983757 | 451.327919 |
| D4 | −207459.983757 | 627.317787 |
| D5 | −90430.481262 | 839.555523 |
| D6 | −90430.481262 | |

The deflection optical unit 13 in accordance with FIG. 19 has an expansion factor of 5 for the x/y-aspect ratio.

In an alternative design regarding FIG. 19, the mirror sequence convex/plane/concave/concave/concave/concave is exactly as the above-described embodiment of the deflection optical unit 13. This alternative design regarding FIG. 19 differs in the specific radii of curvature and mirror distances, as illustrated by the following table:

Table “alternative design regarding FIG. 19”

| | Radius of curvature | Distance to the next mirror |
|---|---|---|
| D1 | 10293.907897 | 192.462359 |
| D2 | 0.000000 | 285.944981 |
| D3 | −101659.408806 | 360.860262 |
| D4 | −101659.408806 | 451.967976 |
| D5 | −101659.408806 | 517.093086 |
| D6 | −101659.408806 | |

This alternative design regarding FIG. 19 has an expansion factor of 4 for the x/y-aspect ratio of the EUV individual output beam 9.

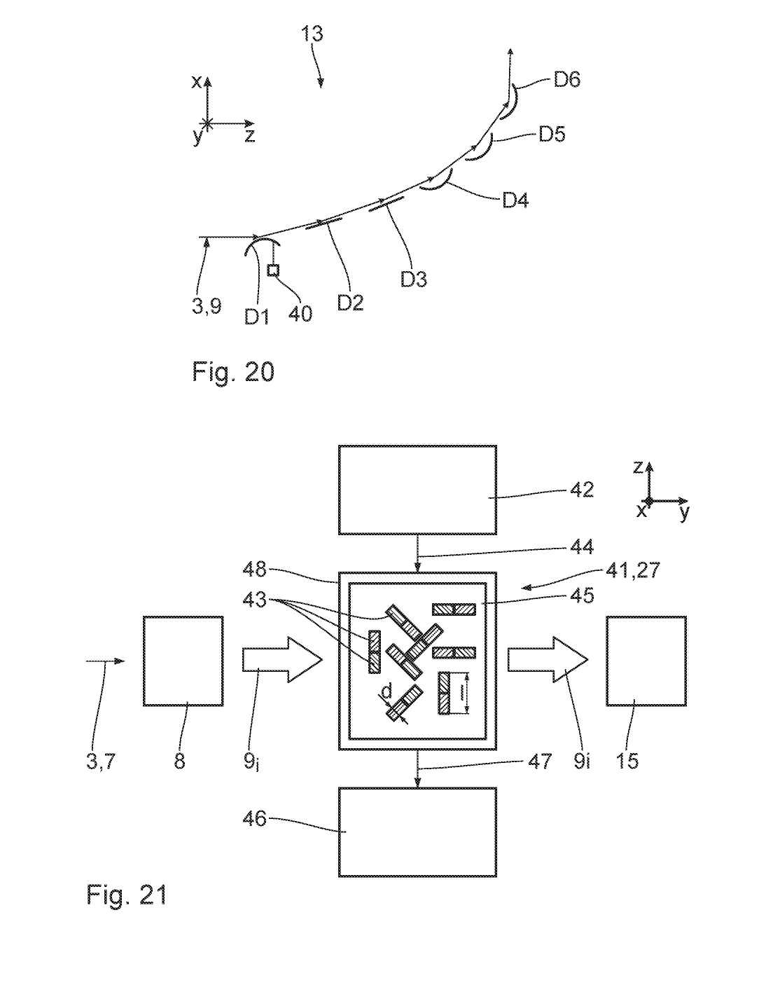

FIG. 20 shows a further embodiment of a deflection optical unit 13 including six mirrors D1 to D6. The first deflection mirror D1 of the deflection optical unit 13 is a convex cylindrical mirror. The two downstream deflection mirrors D2 and D3 are plane mirrors. The downstream deflection mirrors D4 to D6 of the deflection optical unit 13 are concave cylindrical mirrors. The radii of curvature of the last two deflection mirrors D5 and D6 are identical.

More precise data can be gathered from the following table, which corresponds to the table regarding FIG. 19 in terms of layout.

Table regarding FIG. 20

| | Radius of curvature | Distance to the next mirror |
|---|---|---|
| D1 | 8304.649871 | 195.440359 |
| D2 | 0.000000 | 314.991402 |
| D3 | 0.000000 | 435.995630 |
| D4 | −237176.552267 | 622.135962 |
| D5 | −85355.457233 | 852.531832 |
| D6 | −85355.457233 | |

The deflection optical unit 13 in accordance with FIG. 20 has an expansion factor of 5 for the x/y-aspect ratio.

In a further variant (not illustrated) the deflection optical unit has a total of eight mirrors D1 to D8. The two leading deflection mirrors D1 and D2 in the beam path of the EUV individual output beam 9 are concave cylindrical mirrors. The four downstream deflection mirrors D3 to D6 are convex cylindrical mirrors. The last two deflection mirrors D7 and D8 of this deflection optical unit are once again concave cylindrical mirrors.

These mirrors D1 to D8 are connected to actuators 40 in a manner comparable with the mirror D1 in FIG. 14, via which actuators a distance between adjacent mirrors D1 to D8 can be predefined.

The following table shows the design of this deflection optical unit 13 including the eight mirrors D1 to D8, wherein the mirror distances for different semidiameters dₒᵤₜ/2 of the emergent EUV individual output beam 9ᵢ are also indicated besides the radii of curvature. In this case, the EUV individual output beam 9 is incident in the deflection optical unit including eight mirrors D1 to D8 with a semidiameter dᵢₙ/2 of 10 mm, such that expansion factors for the x/y-aspect ratio of the deflected EUV individual output beam 9ᵢ of 4.0, of 4.5 and of 5.0 are realized depending on the distance values indicated.

| | Radius of | | Distances [mm] | |
|---|---|---|---|---|
| | curvature | 40 mm | for 45 mm | 50 mm |
| | [mm] | Semidiameter | semidiameter | Semidiameter |
| D1 | −24933.160828 | 233.314949 | 313.511608 | 355.515662 |
| D2 | −96792.387128 | 261.446908 | 184.453510 | 159.189884 |
| D3 | 13933.786194 | 120.747224 | 278.984993 | 124.048048 |
| D4 | 7248.275614 | 150.818354 | 311.248621 | 385.643707 |
| D5 | 29532.874950 | 204.373669 | 219.654058 | 296.180993 |
| D6 | 100989.002210 | 872.703663 | 698.841397 | 665.602749 |
| D7 | −87933.616578 | 1176.395997 | 1462.002885 | 1318.044212 |
| D8 | −79447.352117 | | | |

In a further embodiment (likewise not illustrated) of the deflection optical unit, four mirrors D1 to D4 are present. The first mirror D1 and the third mirror D3 in the beam path of the EUV individual output beam 9ᵢ are embodied as convex cylindrical lenses and the two further mirrors D2 and D4 are embodied as concave cylindrical lenses. The following table also indicates, besides the radii of curvature, distance values which are calculated for an input semidiameter Dᵢₙ/2 of the EUV individual output beam 9ᵢ of 10 mm, that is to say which lead to expansion factors upon passage through this deflection group including the four mirrors D1 to D4 for the x/y-aspect ratio of 1.5 (semidiameter dₒᵤₜ/2 15 mm), of 1.75 (semidiameter dₒᵤₜ/2 17.5 mm) and of 2.0 (semidiameter dₒᵤₜ/2 20 mm).

| | Radius of | | Distances [mm] | |
|---|---|---|---|---|
| | curvature | 15 mm | for 17.5 mm | 20 mm |
| | [mm] | Semidiameter | semidiameter | Semidiameter |
| D1 | 112692.464497 | 1718.226630 | 6884.616863 | 7163.537958 |
| D2 | −488601.898900 | 250.044362 | 205.433074 | 3185.838011 |
| D3 | 112362.082498 | 1439.444519 | 263.976778 | 175.458248 |
| D4 | −86905.078626 | | | |

The deflection optical unit 13 can be designed in such a way that parallel incident light leaves the deflection optical unit again parallel. The deviation of the directions of rays of the EUV individual output beam 9ᵢ that enter the deflection optical unit 13 with parallel incidence after leaving the deflection optical unit can be less than 10 mrad, in particular less than 1 mrad and in particular less than 100 gad.

The mirrors Di of the deflection optical unit 13 can also be embodied without refractive power, that is to say in plane fashion. This is possible, in particular, if the x/y-aspect ratio of an EUV collective output beam 7 has an aspect ratio of N:1, wherein N is a number of the projection exposure apparatuses 1 to be supplied by the light source 2. The aspect ratio can also be multiplied by a wanted desired aspect ratio.

A deflection optical unit 13 composed of mirrors Di without refractive power can consist of three to ten mirrors, in particular of four to eight mirrors, in particular of four or five mirrors.

The light source 2 can emit linearly polarized light; the polarization direction, that is to say the direction of the electric field strength vector, of the illumination light 3 upon impinging on a mirror of the deflection optical unit 13 can be perpendicular to the plane of incidence. A deflection optical unit 13 composed of mirrors Di without defractive power can consist of fewer than three mirrors, in particular of one mirror.

In the beam guiding optical unit 10, the focusing assembly 14 is disposed downstream of the deflection optical unit 13 in the beam path of the respective EUV individual output beam 9ᵢ. The focusing assembly 14 is also designated as input coupling optical unit. The focusing assembly 14 serves for transferring the respective EUV individual output beam 9ᵢ into an intermediate focus 33 in an intermediate focal plane 34.

The intermediate focus 33 can be arranged in the region of a through opening of a housing of the scanner 5.

Via the deflection optical unit 13 and/or the focusing assembly 14, the respective EUV individual output beam 9ᵢ can be shaped in each case in such a way that it has a predefined divergence and in particular a predefined spatial intensity distribution I*(x, y). The intensity distribution I*(x, y) is, in particular, the intensity distribution of the illumination radiation in the region of a first facet mirror 16.

In other words, the deflection optical unit 13 and/or the focusing assembly 14 form(s) a mechanism for shaping a beam having a predefined spatial intensity distribution I*(x, y) from a beam having a known intensity distribution I₀(x, y).

The illumination optical unit 15 includes a first facet mirror 16 and a second facet mirror 17, the function of which in each case corresponds to that known from the prior art. The first facet mirror 16 can be a field facet mirror, in particular. The second facet mirror 17 can be a pupil facet mirror, in particular. However, the second facet mirror 17 can also be arranged at a distance from a pupil plane of the illumination optical unit 15. This general case is also designated as a specular reflector.

The facet mirrors 16, 17 in each case include a multiplicity of facets 16a, 17a. During the operation of the projection exposure apparatus 1, each of the first facets 16a is respectively assigned one of the second facets 17a. The facets 16a, 17a assigned to one another in each case form an illumination channel of the illumination radiation 3 for illuminating the object field 11 at a specific illumination angle.

The channel-by-channel assignment of the second facets 17a to the first facets 16a is carried out in a manner dependent on a desired illumination, in particular a predefined illumination setting, by the projection exposure apparatus 1. The facets 16a of the first facet mirror 16 can be embodied as displaceable, in particular tiltable, in particular with two degrees of freedom of tilting in each case. The facets 16a of the first facet mirror 16 can be embodied as virtual facets 16a. The latter should be understood to mean that they are formed by a variable grouping of a plurality of individual mirrors, in particular of a plurality of micromirrors. For details, reference should be made to WO 2009/100856 A1, which is hereby incorporated in the present application as part thereof.

The facets 17a of the second facet mirror 17 can correspondingly be embodied as virtual facets 17a. They can also correspondingly be embodied as displaceable, in particular tiltable.

Via the second facet mirror 17 and, if appropriate, via a downstream transfer optical unit (not illustrated in the figures) including three EUV mirrors, for example, the first facets 16a are imaged into the object field 11 in a reticle or object plane 18.

The individual illumination channels lead to the illumination of the object field 11 with specific illumination angles. The totality of the illumination channels thus leads to an illumination angle distribution of the illumination of the object field 11 by the illumination optical unit 15. The illumination angle distribution is also designated as illumination setting.

In a further embodiment of the illumination optical unit 15, in particular given a suitable position of the entrance pupil of the projection optical unit 19, it is also possible to dispense with the mirrors of the transfer optical unit upstream of the object field 11, which leads to a corresponding increase in transmission of the projection exposure apparatus 1 for the used radiation beam.

The reticle 12 having structures that are reflective to the illumination radiation 3 is arranged in the object plane 18 in the region of the object field 11. The reticle 12 is carried by a reticle holder 20. The reticle holder 20 is displaceable in a manner driven via a displacement apparatus 21.

The projection optical unit 19 images the object field 11 into the image field 22 in an image plane 23. The wafer 24 is arranged in the image plane 23 during the projection exposure. The wafer 24 has a light-sensitive coating that is exposed during the projection exposure by the projection exposure apparatus 1. The wafer 24 is carried by a wafer holder 25. The wafer holder 25 is displaceable in a manner controlled via a displacement apparatus 26.

The displacement apparatus 21 of the reticle holder 20 and the displacement apparatus 26 of the wafer holder 25 can be signal-connected to one another. They are synchronized, in particular. The reticle 12 and the wafer 24 are displaceable in particular in a synchronized manner with respect to one another.

During the projection exposure for producing a micro- or nanostructured component, both the reticle 12 and the wafer 24 are displaced in a synchronized manner, in particular scanned in a synchronized manner by corresponding driving of the displacement apparatuses 21 and 26. The wafer 24 is scanned at a scanning rate of 600 mm/s, for example, during the projection exposure.

Further aspects of the system, in particular of the illumination apparatus 35, are described below.

The general construction of a system including a single radiation source 2 and a plurality of scanners 5 is illustrated once again highly schematically in FIG. 3. A system including four scanners 5 is illustrated by way of example in FIG. 3.

It has been recognized that it is advantageous to be able to control, in particular regulate, the radiation power of the illumination radiation 3 at the input of each individual scanner 5. This is advantageous, in particular, in order to be able to control, in particular regulate, in a targeted manner the radiation dose with which the wafer 24 is exposed. The radiation dose with which the wafer 24 is exposed can be predefined, controlled or regulated in particular to an accuracy of approximately 0.1%.

It has furthermore been recognized that an adaptation of the output power of the radiation source 2, in particular of the FEL output power, has the effect that the radiation power at the input of all the scanners 5 is influenced in the same way. The possibility of individually controlling the radiation power used for the exposure of the wafer 24 in each of the scanners 5 is desirable, however.

According to the present disclosure, a device for dose adaptation is provided for this purpose. A device for controlling the intensity distribution 27 of the illumination radiation 3 impinging on the object field 11 serves as the device for dose adaptation. The device for controlling the intensity distribution 27 is embodied as part of the illumination apparatus 35. It can be retrofitted in a system including existing scanners 5 in a simple manner.

In principle, it is also possible to embody the device for controlling the intensity distribution 27 of the illumination radiation 3 impinging on the object field 11 and thus the device for dose adaptation as part of the scanner 5, in particular as part of the illumination optical unit.

The intensity of the illumination radiation 3 that impinges on the object field 11, in particular on the wafer 24, can be detected with the aid of an energy sensor (not illustrated in the figures). This makes it possible to regulate the radiation dose with which the wafer 24 is exposed.

The energy sensor can be arranged in principle, at an arbitrary location in the beam path of the illumination radiation. It can be arranged in particular in the beam path of the illumination optical unit, that is to say upstream of the object field 11. It can also be arranged in the region of the object field 11. It can also be arranged in the beam path of the projection optical unit 19. It can in particular also be arranged in the region of the image field 22 or even behind the latter. It is also possible for a plurality of energy sensors to be provided.

According to the disclosure, it has been recognized that the illumination radiation 3 impinging on the object field 11, in particular the intensity distribution of the illumination radiation, can be controlled by virtue of the fact that the respective individual illumination beam which serves for illuminating the object field 11 with a given intensity distribution is displaced relative to the object field 11. For simplification this is also expressed by the statement that the intensity distribution is displaced relative to the object field 11. Hereinafter, unless indicated otherwise, the intensity distribution should be understood to mean in each case the intensity distribution of the respective EUV individual output beam 9ᵢ.

Generally, the intensity distribution of the illumination radiation 3 impinging on the object field 11 can be controlled by virtue of the fact that the radiation power which is emitted by one of the individual output beams 9ᵢ into a specific phase space volume is altered, in particular controlled, in particular regulated. This can be achieved in particular by displacing the respective individual output beam 9ᵢ and/or influencing the divergence thereof.

A variation of the radiation intensity, in particular of the intensity distribution in the object field 11, can be achieved in particular by virtue of the fact that firstly an intensity distribution I*(x, y), in particular an inhomogeneous intensity distribution I*(x, y), is generated and the latter is displaced relative to the first facet mirror 16. Since exclusively that portion of the illumination radiation 3 which impinges on the first facet mirror 16 contributes to the illumination of the object field 11, the illumination radiation 3 impinging on the object field 11 can thereby be controlled in a simple manner.

A corresponding variant is illustrated schematically in FIGS. 5 and 6. Here the relative position of an intensity profile I(x₁, y) of the illumination radiation 3 in the region of the first facet mirror 16 which corresponds to a specific field height x₁ is illustrated schematically in each case. For elucidating the concept according to the disclosure, that portion of the intensity profile of the illumination radiation 3 which impinges on the first facet mirror 16 and is reflected to the object field 11 is illustrated in a hatched fashion. That portion of the illumination radiation 3 which is not reflected by the first facet mirror 16 and therefore does not contribute to the illumination of the object field 11 is illustrated without hatching.

The situation illustrated in FIG. 5 represents the case of lowest total intensity on the first facet mirror 16, under the boundary condition that all of the first facets 16a are still fully illuminated. The situation illustrated in FIG. 6 correspondingly represents the case of highest total intensity. The ratio of the two hatched areas indicates the possible swing of the intensity adaptation and thus of the dose adaptation.

The intensity profile I(x, y) has in the y-direction an extension that is greater than the extent of the first facet mirror 16 in this direction. The absolute value D is also designated as overhang. What can be achieved as a result is that illumination radiation 3 impinges on all of the first facets 16a even in the case of a displacement of the intensity profile I(x, y) relative to the facet mirror 16. In the scanning direction, in particular, the intensity profile I(x, y) can be longer by an absolute value D than an extension L of the facet mirror 16 in this direction. In this case, the extension of the intensity profile I(x, y) should be understood to mean the extent of the cross section of the illumination beam, in particular in the region of the first facet mirror 16, that is to say the extent of the region in which the intensity profile I(x, y) is greater than 0.

The overhang D can preferably correspond precisely to the scope of displacement that can be realized. The ratio of D to L can be in particular in the range of 0.005 to 0.5, in particular in the range of 0.1 to 0.2. The overhang D can be in the range of 10 mm to 100 mm, in particular in the range of 30 mm to 50 mm.

The intensity profile I(x, y) has a gradient in the scanning direction, ∂/∂y (I(x, y))≠0. The gradient of the intensity profile I(x, y) perpendicular to the scanning direction is preferably =0, ∂/∂x (I(x, y))=0. The intensity profile thus has in particular a gradient running parallel to the scanning direction, that is to say parallel to the y-direction. The intensity profile is chosen in particular in such a way that the intensity distribution I(x, y) perpendicular to the scanning direction is constant, I(x, y₁)=constant, wherein y₁ indicates an arbitrary, but fixed, value in the scanning direction.

An alternative, preferred intensity profile I*(x, y) is illustrated by way of example in FIG. 7. The intensity profile illustrated in FIG. 7 has an exponential progression in the scanning direction, I*(x, y)=I*(x)·exp[a(y+Δ)], wherein a and Δ are predefined constants. In this case, too, it preferably holds true once again that ∂/∂x (I*(x, y))=0.

Such an exponential intensity profile I*(x, y) has the advantage that the ratio of the radiation intensity on two arbitrary, predefined first facets 16a is not altered by the displacement of the intensity profile I*(x, y) relative to the first facet mirror 16.

The following parameters can be calculated from the intensity profile I(x, y): the settable dose ratio γ is given by the ratio of the maximum intensity reflected by the facet mirror 16 to the minimum intensity reflected by the facet mirror 16 under the boundary condition that all of the facets 16a are still fully impinged on by illumination radiation 3. The relative energy loss ε is given by the ratio of the difference between total intensity and maximum intensity to the total intensity, Σ=1−Iₘₐₓ/Iₜₒₜ. The relative inhomogeneity η of the illumination of the facet mirror 16 and thus of the illumination direction distribution of the object field 11 is given by the ratio of the difference between the maximum and minimum intensities on the facet mirror 16, η=(I(L)−I(0))/I(0). The gradient of the relative intensity profile, that is to say the gradient of the intensity at a location divided by the average intensity in the region of the facet mirror, is accordingly approximately η divided by the extent of the first facet mirror 16. The gradient can be in the range of 0.1%/mm to 10%/mm, in particular in the range of 0.3%/mm to 3%/mm, in particular in the range of 0.5%/mm to 2%/mm.

Boundary conditions can be predefined for these parameters. By way of example, it is advantageous to limit the maximum permissible energy levels ε. The boundary condition ε≦0.2, in particular ε≦0.1, has proved to be expedient. The smaller ε is, the greater η tends to be. The resultant values for relative inhomogenity η of the illumination are then approximately in the range of 2 to 3 with the use of an exponential profile. The resultant effects can be compensated for by a suitable channel-by-channel assignment of the second facets 17a to the first facets 16a.

For displacing the intensity profile I*(x, y), the device 27 has a pivotable mirror 28. The mirror 28 can be a plane mirror. The mirror 28 is generally a beam guiding element.

The mirror 28 can have a diameter in the range of 1 mm to 100 mm, in particular in the range of 2 mm to 50 mm, in particular in the range of 3 mm to 30 mm, in particular in the range of 5 mm to 20 mm.

The mirror 28 is arranged at a distance from the first facet mirror 16 in the direction of the beam path of the illumination radiation 3. The distance between the mirror 28 and the first facet mirror 16 in the direction of the beam path of the illumination radiation 3 is in the range of 10 cm to 5 m, in particular in the range of 50 cm to 2 m.

The mirror 28 is displaceable, in particular pivotable. The mirror 28 is pivotable in particular about an axis which is perpendicular or at least approximately perpendicular to the plane of incidence of the illumination radiation 3. In this case, plane of incidence is understood to mean the plane in which the incident beam, the emergent beam and the local surface normal lie. It is pivotable in particular about a pivoting axis oriented parallel to the x-direction. A displacement of the mirror 28 thus leads in particular to a displacement of the intensity profile I*(x, y) relative to the first facet mirror 16. The displacement of the mirror 28 leads in particular to a displacement of the intensity profile I*(x, y) in the y-direction, that is to say parallel to the scanning direction or a direction corresponding to the scanning direction in the region of the first facet mirror 16.

Two piezo-actuators 29 arranged at a distance from one another are provided for pivoting the mirror 28. The piezo-actuators 29, in particular their points of engagement on the mirror 28, have a distance s. The distance s of the piezo-actuators 29 is in particular in the range of 1 mm to 100 mm, in particular in the range of 2 mm to 50 mm, in particular in the range of 3 mm to 30 mm, in particular in the range of 5 mm to 20 mm.

The piezo-actuators 29 are embodied and arranged on the mirror 28 in particular in such a way that the mirror is pivotable by a pivoting angle of up to 20 mrad, in particular up to 50 mrad, in particular up to 100 mrad.

The mirror 28 is arranged in particular in such a way that illumination radiation 3 impinges on it with grazing incidence. The angle of incidence of the illumination radiation 3 on the mirror 28 is in particular at least 45°, in particular at least 60°, in particular at least 70°, in particular at least 80°.

The illumination radiation 3 impinging on the mirror 28 can already be shaped in such a way that the above-described intensity profile I*(x, y) results on the first facet mirror 16. By way of example, the deflection optical unit 13 and/or the focusing assembly 14 serve(s) as mechanisms for shaping the EUV individual output beam 9ᵢ.

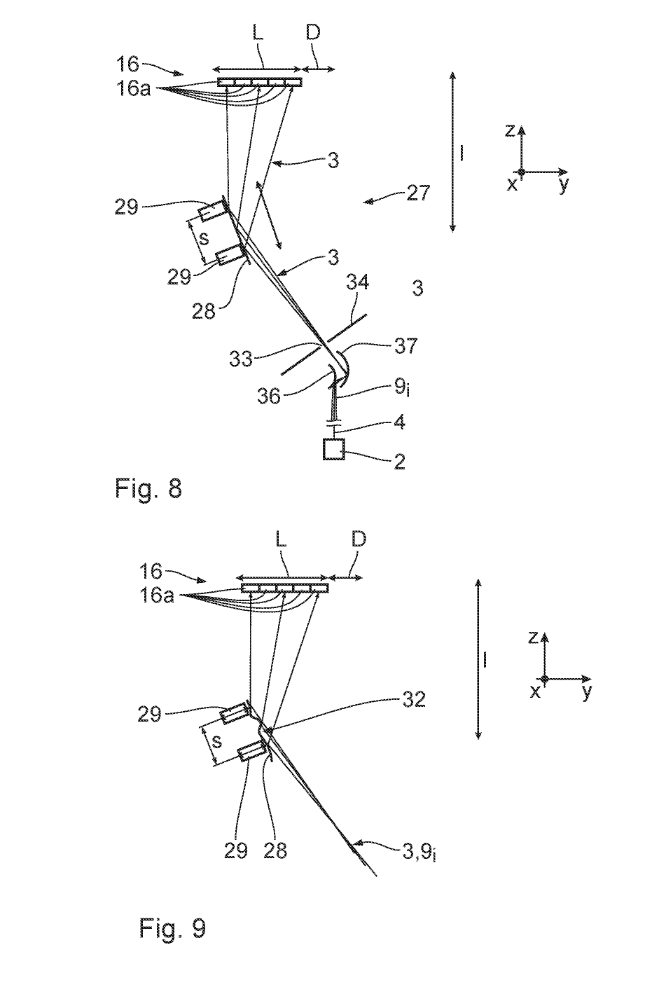

FIG. 8 shows an alternative illustration of the concept according to the disclosure. FIG. 8 illustrates in particular two mirrors 36, 37, which serve as mechanisms for shaping a beam having a predefined spatial intensity distribution I*(x, y) from a beam having a known intensity distribution I₀(x, y), in particular for shaping the EUV individual output beam 9ᵢ.

In the case of the alternative illustrated in FIG. 8, the mirror 28 is arranged in the beam path behind the intermediate focus 33.

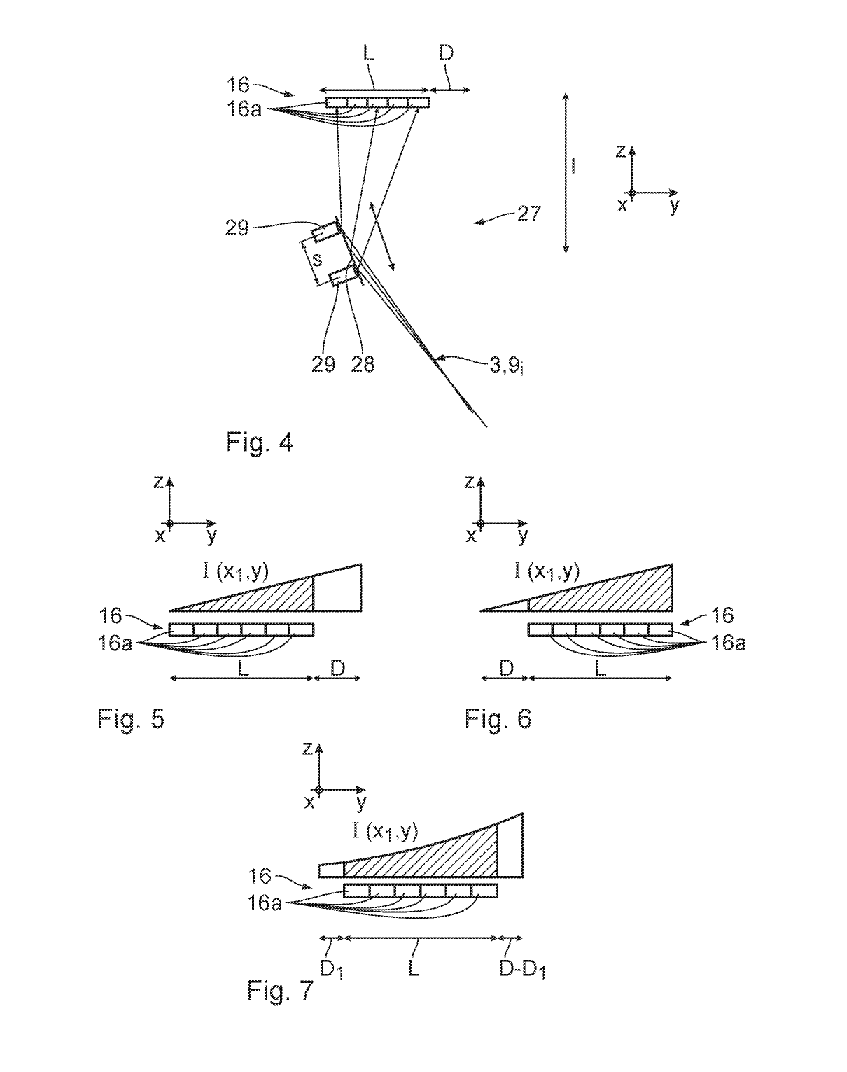

FIG. 9 illustrates a further alternative. The embodiment substantially corresponds to that in accordance with FIG. 4, to the description of which reference is hereby made. In the case of the alternative in accordance with FIG. 9, the surface of the mirror 28 is provided with a surface profile 32 which generates the desired intensity profile I*(x, y) in the region of the first facet mirror 16.

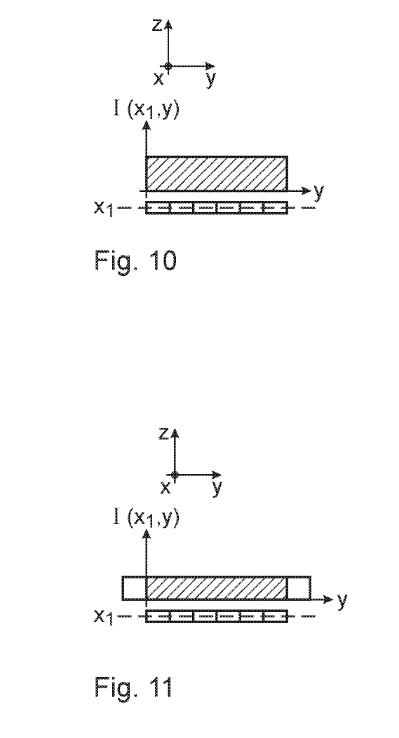

A further alternative is described below with reference to FIGS. 10 and 11. FIGS. 10 and 11 illustrate by way of example an alternative intensity profile I*(x₁, y) before the displacement (FIG. 10) and after the displacement (FIG. 11).

The intensity profile I*(x, y) illustrated in FIGS. 10 and 11 is a so-called flat-top profile. Such a profile has a constant value in a predefined range. It is identical to 0 outside the range.

In this variant, provision is made for implementing the displacement of the intensity profile I*(x, y) in such a way that the total area over which the illumination radiation 3 is distributed is altered. In this variant, in other words, the radiation power emitted into a specific phase space volume is altered by the divergence of the individual output beam 9ᵢ being altered. Since the total power remains constant in this case, the intensity of the illumination radiation 3 impinging on the facet mirror 16 is altered. It is reduced in particular inversely proportionally to the total area on which illumination radiation 3 impinges.

An enlargement of the divergence of the individual output beam 9ᵢ, that is to say an enlargement of the area on which illumination radiation 3 impinges, in particular in the region of the first facet mirror 16, has the effect that a variable proportion of the illumination radiation 3 impinges outside that region of the facet mirror 16 which is useable for the exposure of the object field 11 and therefore does not contribute to the illumination of the reticle 12 in the object field 11.

This variant can also be combined with other intensity profiles, in particular in accordance with one of the variants in the above description.

For displacing the intensity profile I*(x, y) by way of such a change in magnitude, provision is made for embodying the mirror 28 as deformable. As is illustrated schematically in FIG. 13, for this purpose the mirror 28 can be mounted in an immobile fashion at two or more fixed points 39. One or a plurality of piezo-actuators 29 can be arranged in the region between two of the fixed points 39, via which piezo-actuators the mirror 28 can be deformed. The mirror 28 can be deformable with the aid of the piezo-actuators 29 in particular in a direction perpendicular to the connecting line between the fixed points 39.

In this case, the mirror 28 can be embodied and/or mounted in such a way that a surface form is cylindrical. Via a length change of the piezo-actuator or piezo-actuators 29, the mirror can have a surface that is parabolic to a variable extent.

The mirror 28 can be embodied such that it is free of curvature in the x-direction. Inhomogeneities of the illumination radiation 3 in the region of the facet mirror 16 in a direction perpendicular to the scanning direction are avoided as a result.

The piezo-actuator 29 can have a scope of actuation of up to 0.1 mm, in particular up to 0.2 mm, in particular up to 0.3 mm, in particular up to 0.5 mm, in particular up to 0.7 mm, in particular up to 1 mm.

It is also possible to provide more than one piezo-actuator 29 for deforming the mirror 28. It is possible, in particular, for the mirror 28 not to be mounted fixedly in the region of the fixed points 39, but rather via further piezo-actuators. As a result, firstly, the scope of the total possible deformation of the mirror 28 can be increased. In addition, the mirror 28 can thereby be pivoted in accordance with the above description.

The actuation of the mirror 28 for the deformation of the surface thereof via the piezo-actuator 29 is advantageously carried out one-dimensionally. The sag of the surface of the mirror 28 depends in particular exclusively on a single coordinate. In the orthogonal direction with respect thereto, the sag of the surface is advantageously constant.

The deformable mirror 28 is advantageously operated with grazing incidence. The deformable mirror 28 is arranged in the beam path of the illumination radiation 3 in particular in such a way that the angle of incidence of the illumination radiation 3 in the plane state of the mirror 28 is at least 45°, in particular at least 60°, in particular at least 70°, in particular at least 80°.

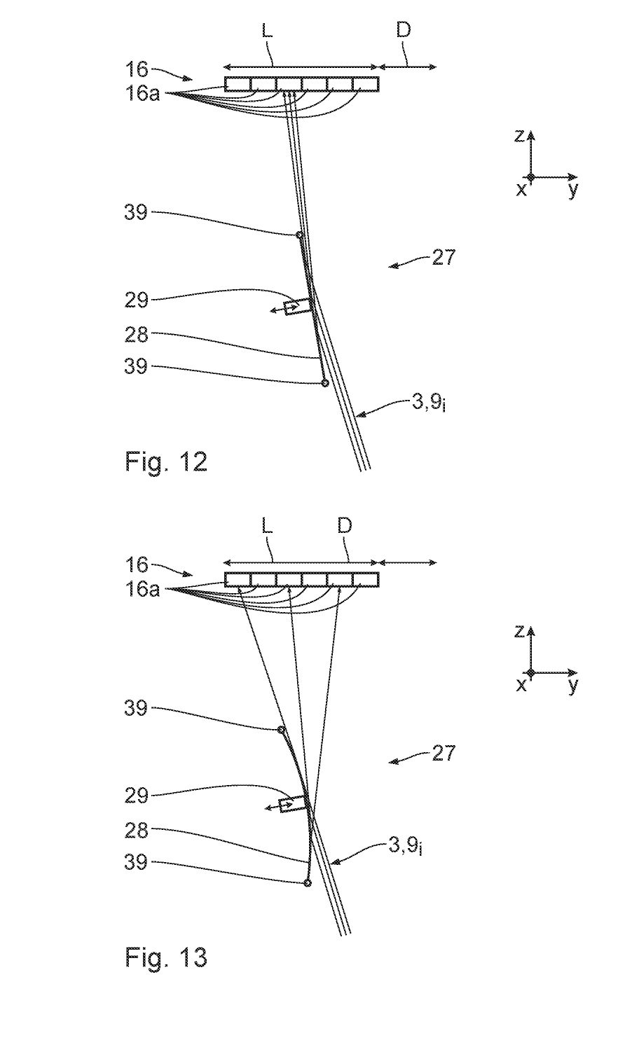

The axis along which the curvature of the mirror 28 can be altered via the piezo-actuator 29 lies at least approximately in the plane of incidence of the illumination radiation 3. This is illustrated schematically in FIGS. 12 and 13.

Furthermore, it has been recognized that the different above-described variants of the displacement of the intensity distribution I*(x, y) relative to the facet mirror 16 can have the effect that the angles of incidence of the illumination radiation 3 on the individual facets 16a change marginally if the mirror 28 is displaced and/or deformed. This can have the effect that the position of the region illuminated on the second facet mirror 17 migrates marginally. In order to minimize this effect, provision can be made for arranging the mirror 28 in the beam path of the illumination radiation 3 in such a way that the first facets 16a image the location of the actuated mirror 28 in each case onto the second facets 17a.

The location of the actuated mirror 28 can correspond to the location of an intermediate focus 33 or be situated in proximity thereto. Such an arrangement can be advantageous particularly when a plasma source is used as the radiation source 2.

The location of the actuated mirror 28 can also be at a distance from the intermediate focus 33. This can be expedient particularly when a radiation source 2 having a small etendue is used, in particular when a free electron laser (FEL) is used. If the actuated mirror 28 is arranged at a distance from the intermediate focus 33, then it may be expedient to design the displacement process in such a way that a translation is also carried out besides a rotation.

The first facets 16a of the first facet mirror 16 can likewise be displaced in a manner dependent on the displacement of the pivotable mirror 28. This can be expedient in particular if the mirror 28 is not arranged at a location which is imaged onto the second facets 17a by the first facets 16a. The first facets 17a and the mirror 28 are advantageously displaced synchronously with one another.

During the production of a micro- or nanostructured component via the projection exposure apparatus 1, firstly the reticle 12 and the wafer 24 are provided. Afterwards, a structure on the reticle 12 is projected onto a light-sensitive layer of the wafer 24 with the aid of the projection exposure apparatus 1. Via the development of the light-sensitive layer, a micro- or nanostructure is produced on the wafer 24 and the micro- or nanostructured component is thus produced. The micro- or nanostructured component can be in particular a semiconductor component, for example in the form of a memory chip.

The system according to the disclosure including a plurality of scanners 5 makes it possible to expose a plurality of wafers 24 simultaneously in separate scanners 5.

In this case, the radiation dose for the exposure of the individual wafers 24 can be individually controlled, in particular regulated, via the illumination apparatus 35 in each of the scanners 5.

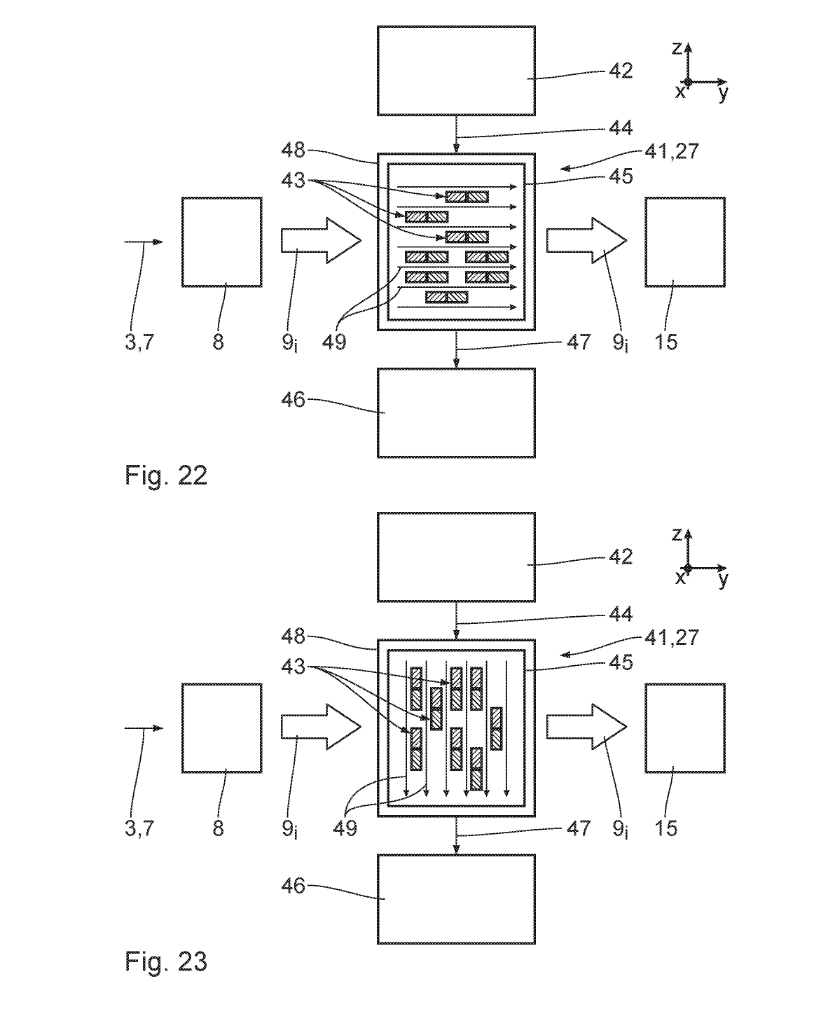

Further alternatives of the device 27 for influencing a respective one of the individual output beams 9ᵢ guided to the illumination optical units 15 are described below with reference to FIGS. 21 to 29.

In all of the alternatives described by way of example, it is possible for the illumination radiation 3, in particular the total intensity of the illumination radiation 3 guided to a respective one of the object fields 11, to be attenuated in a controlled and rapid manner. The amplitude of the influenceability is in particular in the range of a few percent. The rate of the variation of the attenuation is in the range of from a few kilohertz to a few tens of kilohertz.

In the case of the embodiment illustrated in FIGS. 21 to 23, the device 27 includes an apparatus 41 for influencing the vignetting of one of the individual output beams 9ᵢ. The apparatus 41 includes a reservoir 42 for accommodating vignetting particles 43. The vignetting particles 43 can be fed via a feed connection 44 (only indicated schematically) to a volume region, also designated as interaction region 45.

The term interaction region 45 denotes the region in which the illumination radiation 3 of the individual output beam 9ᵢ can interact with one of the mechanisms described below for vignetting and/or absorption of the illumination radiation 3. In particular, a volume region through which one of the individual output beams 9ᵢ passes is involved.

The feed of the vignetting particles 43 to the interaction region 45 can be controllable. It can be actuatable, in particular. In particular, the average density of the vignetting particles 43 in the interaction region 45 can be varied via a control apparatus (not illustrated in the figures).

The apparatus 41 furthermore includes a receptacle reservoir 46. The receptacle reservoir 46 is connected to the interaction region 45 via a discharge connection 47. It serves to receive the vignetting particles 43 after the latter have passed through the interaction region 45.

The particles 43 can move through the interaction region 45 on account of an external force field, in particular on account of the gravitational force. They can in particular trickle through the individual output beam 9ᵢ. A vignetting of the illumination radiation 3 in the individual output beam 9ᵢ occurs in this case. They can in principle also be kept stationary or at least substantially stationary in the interaction region 45.

The apparatus 41 furthermore includes an apparatus 48 for generating a magnetic field in the interaction region 45. The apparatus 48 for generating a magnetic field is arranged in particular outside the interaction region 45. The apparatus 48 can be arranged around the interaction region 45 circumferentially in particular in a direction perpendicular to the direction of propagation of the individual output beam 9ᵢ. It can have a plurality of magnetizable elements. With the aid of the apparatus 48, a magnetic field having a predetermined, changeable direction is generatable in the interaction region 45.

The vignetting particles 43 are embodied in magnetic fashion or have a magnetic movement. They are therefore alignable variably with the aid of the apparatus 48. This is indicated by way of example in FIGS. 21 to 23. FIG. 21 schematically shows the case where the apparatus 48 is not activated and no magnetic field is present in the interaction region 45. The particles 43 have a random orientation in this case.

The vignetting particles 43 are embodied in elongate fashion. They are embodied in rod-shaped fashion. They have a diameter d in the range of 1 μm to 10 μm, in particular in the range of 1 μm to 5 μm. They can have in particular a length in the range of 5 μm to 100 μm, in particular in the range of 10 μm to 50 μm.

It has been found that a sufficiently rapid switching process is possible with particles 43 of this size.

The particles 43 have in particular an aspect ratio (diameter:length) of at most 1:2, in particular at most 1:3, in particular at most 1:5, in particular most 1:10.

In the case illustrated schematically in FIG. 22, the particles 43 have a horizontal orientation which is achievable by the generation of a magnetic field having a first direction with the aid of the apparatus 48. Field lines 49 of the magnetic field which run in the first direction, that is to say horizontally, are illustrated schematically for elucidation purposes.

FIG. 23 illustrates the corresponding case in which the field lines 49 run perpendicularly to the first direction, that is to say vertically, and the particles 43 are therefore aligned vertically.

As a result of the influencing of the alignment of the particles 43, their effective cross section can be influenced. As a result, it is possible to precisely control what proportion of the illumination radiation 3 in the individual output beam 9ᵢ is vignetted by the particles 43.

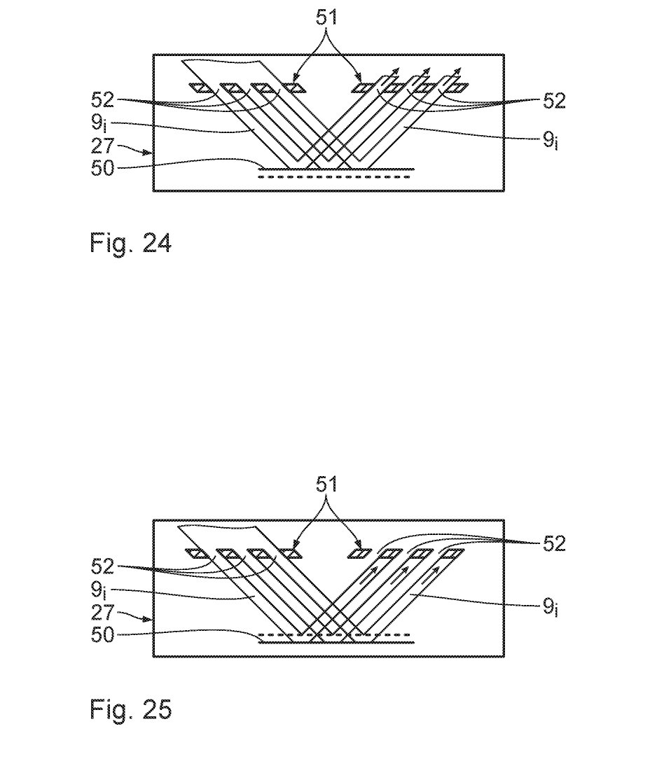

A further alternative of the device 27 is described below with reference to FIGS. 24 to 26. In accordance with this alternative, the device 27 includes a displaceable element 50, which is reflective for the illumination radiation 3. The displaceable element 50 has in particular a reflectivity for the illumination radiation 3 of at least 50%, in particular at least 70%, in particular at least 90%. The illumination radiation 3 can be reflected in particular in a grazing manner at the displaceable element 50. The displaceable element 50 can be embodied in particular in a membranelike fashion. It is switchable in particular with a switching speed of at least 1 kHz. The switching speed of the displaceable element 50 can be more than 2 kHz, in particular more than 3 kHz, in particular more than 5 kHz, in particular more than 10 kHz. It is in particular at most 100 kHz. Vibratory bodies such as are known from loudspeakers can be provided for the displacement of the displaceable element 50.

The device 27 additionally includes two pinhole stops 51. As is illustrated schematically in the figures, via the displacement of the displaceable element 50, it is possible to influence the transmission of the individual output beam 9ᵢ through the system with the two pinhole stops 51. In the case of the example illustrated schematically in FIGS. 24 and 25, the absorption achievable via the device 27 can be varied in a targeted manner between 50% and 100% of the total intensity of the illumination radiation 3 in the individual output beam 9ᵢ. A possible additional absorption upon the reflection at the displaceable element 50 is not taken into account in the indication of the adjustable absorption of the device 27.

Via suitable arrangement and/or design of the passage openings 52 in the pinhole stops 51, in particular in interplay with the displaceability of the displaceable element 50, other adjustment ranges are possible. In particular, it is possible to configure the two pinhole stops 51 periodically and in such a way that, via the displacement of the displaceable element 50, the achievable absorption is adjustable between p and 2 p, wherein the value p is dependent on the configuration of the pinhole stops.

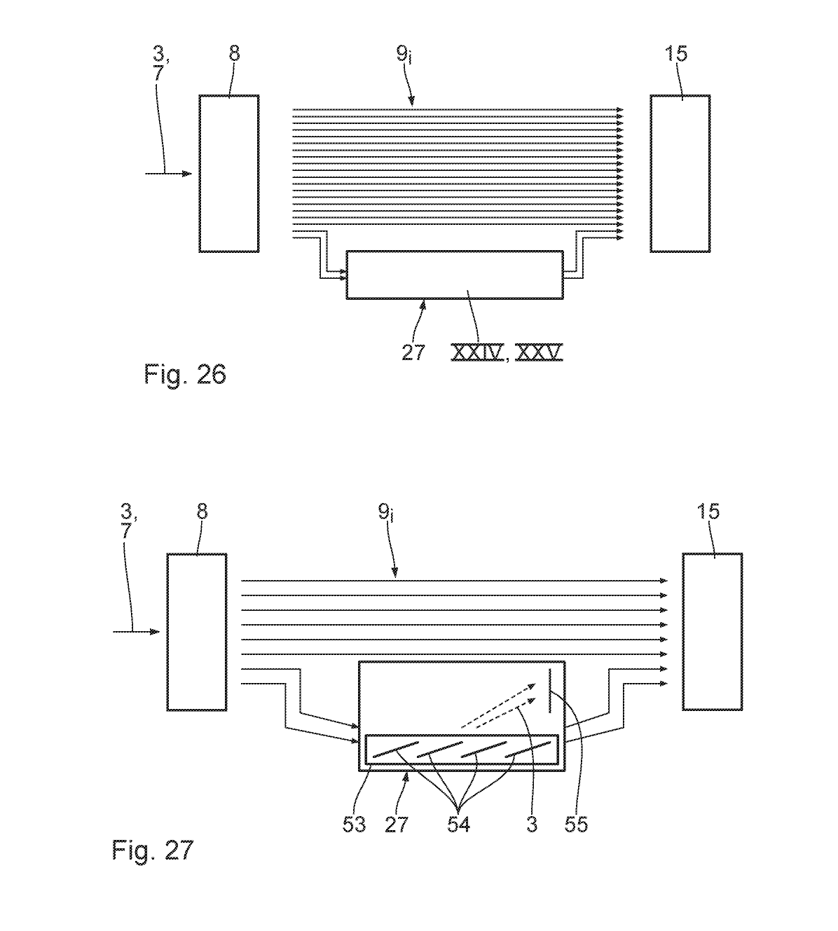

A further possibility for influencing what proportion of the total power of the illumination radiation 3 in the individual output beam 9ᵢ can be absorbed variantly via the device 27 is illustrated schematically in FIG. 26. In accordance with this variant, provision is made for guiding only a portion, for example just 10%, of the total power of the illumination radiation 3 in the individual output beam 9ᵢ through the device 27, while the remainder of the illumination radiation 3 in the individual output beam 9ᵢ is guided past the device 27 and is guided directly to the illumination optical unit 15. This is possible for all of the embodiment alternatives illustrated. This allows, in particular, a reduction of the energy loss that takes place unavoidably upon reflections at elements of the device 27.

A further alternative of the device 27 for influencing one of the individual output beams 9ᵢ is described below with reference to FIG. 27. In the case of this alternative, the device 27 includes a micromirror array 53 as mechanisms for influencing the vignetting of the individual output beam 9ᵢ. The micromirror array 53 includes a multiplicity of switchable micromirrors 54. The micromirrors 54 can be continuously adjustable. They are switchable in particular between two positions. Via the switching of the micromirrors 54, in particular via the switching of a predetermined subset of the micromirrors 54, that proportion of the total intensity of the illumination radiation 3 of the individual output beam 9ᵢ which is guided to a specific illumination optical unit 15 can be controlled precisely and rapidly.

The micromirror array 53 can be in particular a so-called digital micromirror element (Digital Micromirror Device, DMD).

Via the micromirror array 53, a predetermined proportion of the illumination radiation 3 of the individual output beam 9ᵢ can be coupled out from the beam path leading to the illumination optical unit 15. The coupled-out portion of the illumination radiation 3 can be guided in particular onto a stop 55.

In accordance with one alternative of this embodiment, provision is made for arranging, instead of the micromirror array 53, a matrixlike arrangement of microscopic stop elements, as it were a microstop array, in the beam path of one of the individual output beams 9ᵢ. Via a switchability of the microstops corresponding to the switchability of the micromirrors 54 of the micromirror array 53, it is possible to influence their arrangement in the beam path of the individual output beam 9ᵢ and thus their effective cross section, that is to say their stop effect.

The switching frequency of the micromirrors 54 of the micromirror array 53 is in the range of 1 kHz to 100 kHz. The switching frequency of the micromirrors 54 of the micromirror array 53 can also be more than 100 kHz. It is possible, in particular, to switch the micromirrors 54 multiply within one millisecond in order in this way to achieve in particular a finer gradation of that proportion of the individual output beam 9ᵢ which can be stopped down.

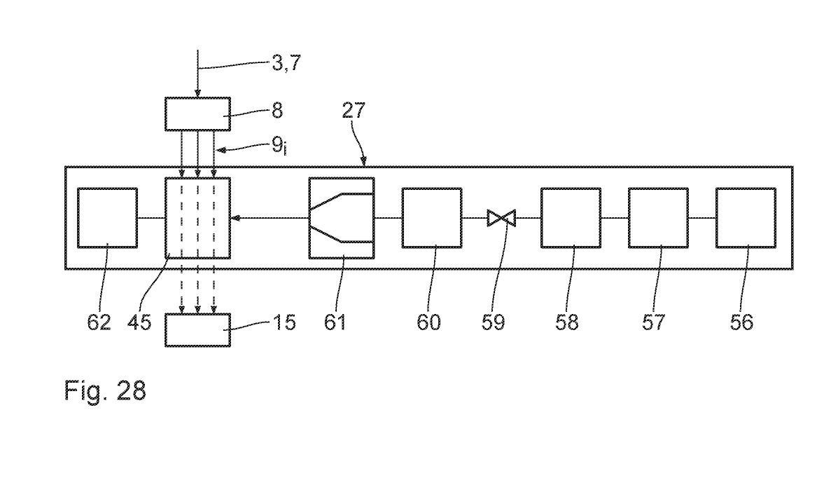

A further alternative of the device 27 is described below with reference to FIG. 28. In accordance with the alternative illustrated in FIG. 28, the device 27 includes a mechanism for influencing the absorption of the illumination radiation 3 in one of the individual output beams 9ᵢ. The mechanism is formed in particular by an apparatus for influencing the average gas density in the interaction region 45. The apparatus is in particular an apparatus for controlling a gas flow, in particular an actuatable apparatus for controlling a gas flow. The apparatus includes a gas reservoir 56, from which gas with a predetermined gas pressure and a predetermined temperature can flow. A pressure reducer 57 is disposed downstream of the gas reservoir 56 in the flow direction. The gas pressure can be reduced to a predetermined value via the pressure reducer 57.

Disposed downstream of the pressure reducer 57 is a throttling apparatus 58 including one or a plurality of throttling units. The latter serve to reduce the pressure further. A valve 59 is disposed downstream of the throttling apparatus 58. The valve 59 is a controllable valve 59, in particular. The valve 59 is switchable in particular at a rate of at least 1 kHz.

A heating apparatus 60 is disposed downstream of the valve 59. Generally, the heating apparatus 60 is a temperature control apparatus for controlling the temperature of the gas, in particular the gas which flows through the interaction region 45.

The gas is introduced, in particular injected, into the interaction region 45 via a nozzle 61.

The nozzle 61 is arranged at a distance of a few centimetres from the individual output beam 9ᵢ. The distance between the nozzle 61 and the interaction region 45 and also the speed of the gas ejected from the nozzle determine a time required by the gas to pass from the nozzle into the interaction region. The time is advantageously less than 5 ms, in particular less than 1 ms, in particular less than 0.5 ms, in particular less than 0.3 ms, in particular less than 0.2 ms, in particular less than 0.1 ms.

A receptacle reservoir 62 for receiving the gas after flowing through the interaction region 45 is arranged on the opposite side of the interaction region 45 relative to the nozzle 61. The receptacle reservoir can include an extraction apparatus (not illustrated in the figure). The gas flow in the interaction region 45 can thereby be controlled in an even more targeted manner.

Via a control of the gas density in the interaction region 45, in particular via a control of the gas pressure and/or of the gas flow in the interaction region 45, it is possible to control in a targeted manner what proportion of the illumination radiation 3 in the individual output beam 9ᵢ is absorbed by the gas flowing through the interaction region 45.

It has been found that the speed of the gas in the interaction region 45 is substantially dependent on the gas temperature in the region before the nozzle 61. Suitable values for gas pressure at the exit of the nozzle 61 and gas temperature at the entrance of the nozzle are represented for different possible gases in Table 1.

TABLE 1

| Element | T [K] | p [Pa] |
|---|---|---|
| H₂ | 9 | 3751 |
| He | 35 | 357.0 |
| Cl₂ | 325 | 83.9 |
| N₂ | 130 | 77.4 |
| Ar | 347 | 136.4 |
| O₂ | 148 | 44.7 |
| F₂ | 176 | 28.9 |
| Kr | 727 | 41.5 |
| Ne | 251 | 41.1 |
| Xe | 1134 | 7.5 |

The indicated values have the effect that 5% of the energy of the individual output beam 9ᵢ is absorbed in the interaction region 45 over a distance of 1 cm. For other geometries and/or requirements, these indications can be scaled in accordance with the fundamental equations of thermodynamics.

The corresponding gas pressure can be set with the aid of the pressure reducer 57 and/or the throttling apparatus 58. The corresponding temperature can be set with the aid of the heating apparatus 60 and/or the temperature control apparatus.

It has been found that with a corresponding device 27 and the indicated values for the gas pressure and the gas temperature, an absorption of the illumination radiation 3 in the individual output beam 9ᵢ is precisely controllable in the range of up to 5%, in particular up to 10%. On account of the rapid switchability of the valve 59, the sufficiently high gas speed and the sufficiently small distance between nozzle 61 and interaction region 45, the absorption variation is possible with the switching time of less than 1 ms, in particular less than 0.5 ms, in particular less than 0.3 ms, in particular less than 0.2 ms, in particular less than 0.1 ms.

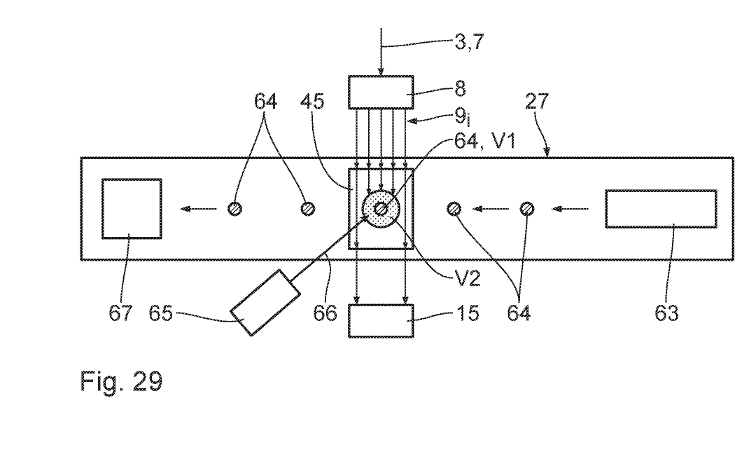

An alternative of the device 27 including a mechanism for influencing the average gas density in the interaction region 45 is described below with reference to FIG. 29. In this variant, the device 27 includes a droplet generator 63. The droplet generator 63 serves to generate liquid droplets 64. The liquid droplets 64 are generated periodically, in particular. The generation of the liquid droplets 64 can be carried out in a non-actuated manner. It is carried out in particular with a frequency in the range of kilohertz, in particular in the range of at least 10 kHz. It can also be carried out in an actuated manner, in particular in a controlled manner.

The liquid droplets 64 are shot into, in particular through, the interaction region 45. The speed at which the generated liquid droplets 64 move in the direction of the interaction region 45 can be so great, in particular, that the time for reaching the interaction region 45 is less than 1 ms. This can be the case, in particular, if the liquid droplets 64 are generated in an actuated manner.

The speed at which the generated liquid droplets 64 move in the direction of the interaction region 45 can in particular also be so low that the time for reaching the interaction region 45 is at least 1 ms. This can be the case, in particular, if the liquid droplets 64 are generated in a non-actuated manner.

The liquid droplets 64 are shot in particular through the beam path of the individual output beam 9ᵢ.

The device 27 furthermore includes an apparatus for evaporating the liquid droplets 64. The apparatus for evaporating the liquid droplets 64 is formed in particular by a laser 65. The laser 65 is activatable in a controlled manner. A laser beam 66 is generatable via the laser 65. The laser beam 66 is adjusted in such a way that it crosses the trajectory of the liquid droplets 64. Via suitable activation of the laser 65, it is possible to evaporate the liquid droplets 64, in particular in the interaction region 45. In the operated state, the droplets 64 occupy a significantly larger volume V2 than their volume V1 in the liquid state. This is indicated schematically in FIG. 29. In the evaporated state, therefore, the effective cross section of the droplets 64 and thus the interaction with the individual output beam 9ᵢ are significantly greater, which has the effect that a larger proportion of the illumination radiation 3 is removed from the individual output beam 9ᵢ by absorption.

A collecting reservoir 67 for collecting the non-evaporated liquid droplets 64 can in turn be arranged on the opposite side of the interaction region 45 relative to the droplet generator 63. The collecting reservoir 67 can also serve for receiving the gas of the evaporated liquid droplets 64.

Preferably, substances which are gaseous under normal conditions (273.15 K, 101.325 kPa) are chosen for the liquid droplets 64.

Possible values for the radius of the liquid droplets 64 and the temperature at which liquefaction occurs under normal pressure (101.325 kPa) are listed in Table 2:

TABLE 2

| Element | r [μm] | T [K] |
|---|---|---|
| H | 356 | 21 |
| He | 162 | 4 |
| Cl | 116 | 17 |
| N | 104 | 77 |
| Ar | 118 | 87 |
| O | 75 | 90 |
| F | 68 | 85 |
| Kr | 85 | 120 |
| Ne | 75 | 27 |
| Xe | 52 | 165 |

The indicated values have the effect that after evaporation of the sphere in a cube of 1 cm³ a gas density arises which has the effect that 20% of the energy of an individual output beam 9ᵢ passing through is absorbed. For other geometries and/or requirements, the values can be scaled in accordance with the fundamental equations of thermodynamics.

What is claimed is:

1. An apparatus, comprising:
an output coupling optical unit configured to generate a plurality of individual output beams from a common collective output beam;
at least two illumination optical units configured to transfer illumination radiation in different individual output beams into separate object fields; and
a device configured to influence at least one of the individual output beams guided to the illumination optical units,
wherein the device has a regulation bandwidth of at least 1 kHz, and the apparatus is a microlithography illumination apparatus.

2. The apparatus of claim 1, wherein the device is in a beam path of the illumination radiation between the output coupling optical unit and one of the object fields.

3. The apparatus of claim 1, wherein the device comprises a mechanism configured to alter a radiation power emitted by the individual output beam into a specific phase space volume.

4. The apparatus of claim 1, wherein the device comprises a mechanism configured to spatially displace the individual output beam relative to an aperture-delimiting element of the illumination optical unit.

5. The apparatus of claim 4, wherein the mechanism configured to displace the individual output beam is configured so that a ratio of a maximum displaceability of the individual output beam in a first direction which is perpendicular to a direction of an optical axis of the apparatus to the extent of the individual output beam in the first direction is at least 0.01.

6. The apparatus of claim 4, wherein the device further comprises a mechanism configured to influence a divergence of the individual output beam.

7. The apparatus of claim 1, wherein the device comprises a mechanism configured to influence a divergence of the individual output beam.

8. The apparatus of claim 1, wherein the device comprises a beam guiding element configured to displace the individual output beam, and the beam guiding element is actuator-displaceable and/or actuator-deformable.

9. The apparatus of claim 8, wherein the mechanism configured to displace the individual output beam is configured so that a ratio of a maximum displaceability of the individual output beam in a first direction which is perpendicular to a direction of an optical axis of the apparatus to the extent of the individual output beam in the first direction is at least 0.01.

10. The apparatus of claim 8, wherein the beam guiding element has a surface profile configured to lead to a specific influencing of the intensity distribution.

11. The apparatus of claim 10, wherein the mechanism configured to displace the individual output beam is configured so that a ratio of a maximum displaceability of the individual output beam in a first direction which is perpendicular to a direction of an optical axis of the apparatus to the extent of the individual output beam in the first direction is at least 0.01.

12. An illumination system, comprising:
an illumination apparatus according to claim 1; and
a common radiation source configured to generate the illumination radiation,
wherein the illumination system is a microlithography illumination system.

13. The illumination system of claim 12, wherein the radiation source comprises a free electron laser or a synchrotron radiation source.

14. A system, comprising:
an illumination system, comprising:
an illumination apparatus according to claim 1; and
a common radiation source configured to generate the illumination radiation; and
at least two projection optical units configured to image the object fields into image fields,
wherein the system is a microlithography projection exposure system.

15. The system of claim 14, wherein a separate projection optical unit is assigned to each illumination optical unit.

16. A method, comprising:
providing a microlithography projection exposure system, comprising:
an illumination system, comprising:
an illumination apparatus according to claim 1; and
a common radiation source configured to generate the illumination radiation; and
at least two projection optical units configured to image the object fields into image fields,
using the illumination system to illuminate a reticle; and
using the at least to projection optical units to project the illuminated reticle onto a wafer.

17. The method of claim 16, comprising using the illumination system to control the intensity distribution of the illumination radiation impinging on the reticle to adapt the radiation dose used to expose the wafer.

18. The method of claim 17, wherein adapting the radiation dose comprises controlling the intensity distribution impinging on the reticle by displacing and/or deforming a beam guiding element, and wherein the time for displacing and/or deforming the beam guiding element is less than a time duration for a point on the wafer to pass through a scanning slot.

19. The method of claim 16, comprising simultaneously exposing a plurality of wafers in separate scanners.

20. An apparatus, comprising:
an output coupling optical unit configured to generate a plurality of individual output beams from a common collective output beam;
a first optical illumination unit configured to transfer radiation in a first set of individual output beams into a first object field;
a second optical illumination unit configured to transfer radiation in a second set of individual output beams into a second object field; and
a device configured to influence at least one of the individual output beams guided to the illumination optical units,
wherein:
the first optical illumination unit is different from the second optical illumination unit;
the first set of individual output beams is different from the second set of individual output beams,
the first object field is different from the second object field;
the device has a regulation bandwidth of at least 1 kHz; and
the apparatus is a microlithography illumination apparatus.
